(19) United States
(12) Patent Application Publication
(10) Pub. No.: US 2006/0223005 A1
(43) Pub. Date: Oct. 5, 2006

(54) Lithographic printing plate support and presensitized plate

(75) Inventor: Hisashi Hotta, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/391,420

(22) Filed: Mar. 29, 2006

(30) Foreign Application Priority Data
Mar. 29, 2005 (JP) 2005-095128

(51) Int. Cl. G03F 7/00

(52) U.S. Cl. 430/300

(57) ABSTRACT

Disclosed is a lithographic printing plate support obtainable by subjecting an aluminum plate to an electrochemical graining treatment with an aqueous solution containing hydrochloric acid, anodizing treatment and alkali metal silicate treatment at least, wherein: a surface of the support has a grained shape in which large pits with a mean aperture diameter of 2 to 10 μm and small pits with a mean aperture diameter of 0.05 to 0.8 μm overlap with each other, with the mean ratio of depth to aperture diameter of the small pits being 0.2 to 0.6; a surface area difference ΔS⁵⁰ defined by equation (1):
ΔS⁵⁰=(Sₓ⁵⁰−S₀⁵⁰)/S₀⁵⁰×100 (%) (1)
in which Sₓ⁵⁰ is the actual area of a 50 μm square region of the surface as determined by three-point approximation from three-dimensional data obtained by measuring the region with an atomic force microscope at 512×512 points and S₀⁵⁰ is the geometrically measured area of the same region, is 20 to 40%; the alkali metal silicate treatment is performed using an aqueous solution of pH 11.5 to 13.0 which contains an alkali metal silicate; and an amount of Si atoms deposited to the surface is 3.0 to 15.0 mg/m². The presensitized plate according to the present invention allows not only the press life but also the resistance to scumming by ink spreading, resistance to scumming by leaving and resistance to scumming by failed deletion, and the water visibility as well, to be excellent, even if an FM screen is used for halftone.

The entire contents of the documents cited in this specification are herein incorporated by reference.

### BACKGROUND OF THE INVENTION

The present invention relates to a lithographic printing plate support which is obtained by subjecting an aluminum plate to electrochemical graining treatment, anodizing treatment and alkali metal silicate treatment at least, and a presensitized plate which is fabricated by using such a lithographic printing plate support.

A presensitized plate for lithographic printing is generally fabricated by subjecting the surface of an aluminum plate to graining treatment such as mechanical graining treatment and electrochemical graining treatment and further to anodizing treatment so as to form an anodized layer, and forming a photosensitive layer (hereafter also referred to as “image recording layer”) on the anodized layer by applying thereto a photosensitive solution and causing the solution to dry. On such a presensitized plate, imagewise exposure and then development with a developer are performed so as to remove the exposed or non-exposed areas depending on whether the presensitized plate is of a positive or negative type, to thereby make a lithographic printing plate.

The lithographic printing plate obtained as above is subsequently mounted on the plate cylinder of a printing press and supplied on the surface with ink and a fountain solution for the purpose of printing on paper, whereupon the portion of the plate where the photosensitive layer remains exhibits a high ink receptivity as an image area and the portion where the photosensitive layer has been removed exhibits a high water wettability as a non-image area.

The surface of a lithographic printing plate support is required to have a number of conflicting properties: For instance, the surface be excellent in water wettability because it is allotted for non-image areas and, at the same time, have a good adhesion to the image recording layer that is formed thereon. If the surface of a lithographic printing plate support has too low a water wettability, non-image areas will be stained with ink during printing to cause ink buildup on the blanket cylinder and, in turn, scumming. In other words, the scumming resistance of a printing plate will be reduced. On the other hand, if the adhesion between the lithographic printing plate support and the image recording layer is poor, the image recording layer is liable to peel off, lowering the durability (press life) of a printing plate when a large number of printed sheets are to be made.

In presensitized plates, accordingly, the adhesion between the image recording layer and the lithographic printing plate support is improved by, for instance, roughening (graining) the surface of an aluminum plate to provide asperities thereon or forming an intermediate layer between the image recording layer and the lithographic printing plate support, and again, the water wettability of the surface of the lithographic printing plate support is increased by performing alkali metal silicate treatment (also referred to simply as “silicate treatment” or “hydrophilizing treatment”) for improving the water wettability of the aluminum plate surface before the image recording layer is formed.

As an example, JP 2-185493 A describes a method of manufacturing a lithographic printing plate support, in which an anodized aluminum plate is treated with an aqueous alkali metal silicate solution which contains hydroxide and has a pH of 12.4 to 13.0 and a specific gravity of 1.02 to 1.17 at 25° C. as well as an electrical conductivity of 35 to 180 [mS/cm] at 70° C.

JP 10-282645 A describes a photosensitive lithographic printing plate in which an intermediate layer is formed on a hydrophilized aluminum support, which layer contains a polymeric compound having a constituent bearing an acid group and a constituent bearing an onium group, and a positive-type photosensitive layer is formed on the intermediate layer.

Moreover, JP 2004-219661 A describes a presensitized plate in which a thermosensitive layer.whose solubility in an aqueous alkali solution is changed by heating is formed on an aluminum support and the surface of the aluminum support has Si atoms deposited thereto in an amount of 5 to 20 mg/cm².

JP 2004-249693 A describes a presensitized plate comprising a lithographic printing plate support obtained by subjecting an aluminum plate to an electrochemical graining treatment with an aqueous solution containing hydrochloric acid, anodizing treatment and alkali metal silicate treatment at least, and also comprising an image recording layer allowing an image to be formed by heat which is provided on the support. The surface of the lithographic printing plate support has a grained shape in which large pits with a mean aperture diameter of 2 to 10 pm and small pits with a mean aperture diameter of 0.05 to 0.8 μm overlap with each other, with the ratio of depth to aperture diameter of the small pits being 0.2 to 0.6 on average. The surface area difference ΔS⁵⁰ defined by the following equation (1) with respect to the surface of the lithographic printing plate support is 20 to 40%:
ΔS⁵⁰=(Sₓ⁵⁰−S₀⁵⁰)/S₀⁵⁰×100 (%) (1)
in which Sₓ⁵⁰ is the actual area of a 50 μm square region of the support surface as determined by three-point approximation from three-dimensional data obtained by measuring the region with an atomic force microscope at 512×512 points, and S₀⁵⁰ is the geometrically measured area of the same region. The amount of the Si atoms deposited to the surface of the lithographic printing plate support is 1.0 to 15.0 mg/m².

### SUMMARY OF THE INVENTION

In a printed material, a region of shadows has a high halftone dot area ratio (70 to 90%) and in the corresponding region of a lithographic printing plate, image areas (remains of the image recording layer) are large in area and non-image areas (bared parts of the support) are small accordingly.

In this regard, ink on one image area and that on an adjacent image area are liable to come into contact with each other (that is to say, ink spreading will readily occur) so as to cause the non-image area between the two image areas to be stained with ink particularly when the feed of fountain solution is reduced during printing, which will result in the plugging (namely, scumming) in a non-image area of a printed material. Such a phenomenon is referred to as “scumming by ink spreading”.

Recently, use of FM screens is increasingly required for high-resolution printing. The scumming by ink spreading as above, however, tends to occur during FM screen printing, in which the image density is adjusted with the density of halftone dots so that the distance between adjacent dots in a region of shadows is small as compared with the case of AM screen printing where the image density is adjusted with the dot size.

Adhesion of dust and so forth sometimes causes the image recording layer of a presensitized plate to remain after development in the areas from which it should be removed. In that case, it is expected that the image recording layer be removed thoroughly from the areas by using a deletion fluid containing a solvent such as used for the application of the layer and an acid such as phosphoric acid.

If the image recording layer, intermediate layer or the like is still left in the areas to which the deletion fluid has been applied, the areas will be stained with ink during printing, with scumming being thus generated in non-image areas. This phenomenon is referred to as “scumming by failed deletion”.

Again, the lithographic printing plate left in place during a possible temporary stop of printing will be so fouled in non-image areas under the influence of atmospheric pollution, for instance, that scumming is generated in the printed materials that are made directly after the temporary stop of printing. Such scumming is called “scumming by leaving”. The scumming by leaving involves certain disadvantages such as waste of paper for printing because of a trial necessary for success in normal printing.

In addition, during the printing with a lithographic printing plate, the balance between the amounts of ink and a fountain solution is adjusted by an operator who visually inspects the shininess of non-image areas of the printing plate surface. The inspectability in shininess, so-called water visibility, is thus one of the important properties of lithographic printing plates.

It is therefore required to make lithographic printing plates excellent not only in press life but also resistance to scumming by ink spreading, resistance to scumming by leaving and resistance to scumming by failed deletion, and in water visibility as well.

Reviewing the proposals about hydrophilizing treatment or formation of an intermediate layer as described before, they are not intended to improve the resistance to the scumming by ink spreading when an FM screen is used for halftone and, accordingly, not effective enough to provide a presensitized plate which allows not only the press life but also the resistance to scumming by ink spreading, resistance to scumming by leaving and resistance to scumming by failed deletion, and the water visibility as well, to be excellent under use of an FM screen for halftone.

Hence an object of the present invention is to provide a presensitized plate which allows not only the press life but also the resistance to scumming by ink spreading, scumming by leaving and scumming by failed deletion, and the water visibility as well, to be excellent, even if an FM screen is used for halftone.

After extensive studies in order to achieve the above and other objects, the inventor of the present invention has found that, if the surface shape of a lithographic printing plate support, the pH of the aqueous solution used in alkali metal silicate treatment, and the amount of the Si atoms deposited to the support surface are each determined within a specified range, the press life of the lithographic printing plate prepared will be improved, and the resistance to scumming by ink spreading, resistance to scumming by leaving and resistance to scumming by failed deletion, and the water visibility as well, will be excellent when an FM screen is used for halftone.

Consequently, the present invention provides the following (I) to (IV).

(I) A lithographic printing plate support obtainable by subjecting an aluminum plate to an electrochemical graining treatment with an aqueous solution containing hydrochloric acid, anodizing treatment and alkali metal silicate treatment at least, wherein: a surface of the support has a grained shape in which large pits with a mean aperture diameter of 2 to 10 μm and small pits with a mean aperture diameter of 0.05 to 0.8 μm overlap with each other, with the mean ratio of depth to aperture diameter of the small pits being 0.2 to 0.6; a surface area difference ΔS⁵⁰ defined by equation (1):
ΔS⁵⁰=(Sₓ⁵⁰−S₀⁵⁰)/S₀⁵⁰×100 (%) (1)
in which Sₓ⁵⁰ is the actual area of a 50 μm square region of the surface as determined by three-point approximation from three-dimensional data obtained by measuring the region with an atomic force microscope at 512×512 points and S₀⁵⁰ is the geometrically measured area of the same region, is 20 to 40%; the alkali metal silicate treatment is performed using an aqueous solution of pH 11.5 to 13.0 which contains an alkali metal silicate; and an amount of Si atoms deposited to the surface is 3.0 to 15.0 mg/m².

(II) A presensitized plate comprising the lithographic printing plate support according to (I) above on which an image recording layer allowing an image to be formed by heat is provided.

(III) The presensitized plate according to (II) above, wherein an intermediate layer is provided between the lithographic printing plate support and the image recording layer, and the intermediate layer is formed with a polymeric material which includes a constituent bearing an acid group and a constituent bearing an onium group.

(IV) The presensitized plate according to (III) above, wherein the intermediate layer contains a polymeric compound which includes 60 to 80 mol % of the constituent bearing an acid group and 20 to 40 mol % of the constituent bearing an onium group.

As will be described later, the presensitized plate according to the present invention allows not only the press life but also the resistance to scumming by ink spreading, resistance to scumming by leaving and resistance to scumming by failed deletion, and the water visibility as well, to be excellent, even if an FM screen is used for halftone.

In other words: An image can be printed with the scumming in non-image areas being prevented even upon FM screen printing; waste of paper for printing due to a temporary stop of printing can be decreased; no image recording layer or intermediate layer remains in the areas to which an deletion. fluid has been applied for the purpose of removing unwanted image recording layer portions after development, so that it is possible to print an image while preventing the scumming in non-image areas; and the balance between the amounts of ink and a fountain solution is readily adjustable during printing.

### BRIEF DESCRIPTION OF THE DRAWINGS

In the accompanying drawings:

FIG. 1 is a side view conceptually showing the processes of brush graining employed in a mechanical graining treatment which is performed in the fabrication of the lithographic printing plate support of the present invention;

FIG. 2 is a cross-sectional view of an example of the electrolytic graining treatment apparatus provided with a flat-type AC electrolytic cell that is used to fabricate the lithographic printing plate support of the present invention;

FIG. 3 is a cross-sectional view of another example of the electrolytic graining treatment apparatus provided with a flat-type AC electrolytic cell that is used to fabricate the lithographic printing plate support of the present invention;

FIG. 4 is a cross-sectional view of an example of the electrolytic graining treatment apparatus provided with a radial-type AC electrolytic cell that is used to fabricate the lithographic printing plate support of the present invention; and

FIG. 5 is a graph showing an exemplary waveform of the alternating current used in an electrochemical graining treatment which is performed in the fabrication of the lithographic printing plate support of the present invention.

### DETAILED DESCRIPTION OF THE INVENTION

Hereafter, the present invention is described in detail.

[Lithographic Printing Plate Support]

The lithographic printing plate support of the present invention is such that a surface of the support has a grained shape in which large pits with a mean aperture diameter of 2 to 10 μm and small pits with a mean aperture diameter of 0.05 to 0.8 μm overlap with each other, with the mean ratio of depth to aperture diameter of the small pits being 0.2 to 0.6; the surface area difference ΔS⁵⁰ defined by equation (1):
ΔS⁵⁰=(Sₓ⁵⁰−S₀⁵⁰)/S₀⁵⁰×100 (%) (1)
in which Sₓ⁵⁰ is the actual area of a 50 μm square region of the surface as determined by three-point approximation from three-dimensional data obtained by measuring the region with an atomic force microscope at 512×512 points and S₀⁵⁰ is the geometrically measured area of the same region, is 20 to 40%; the surface is subjected to an alkali metal silicate treatment using an aqueous solution of pH 11.5 to 13.0 which contains an alkali metal silicate; and the amount of the Si atoms deposited to the surface is 3.0 to 15.0 mg/m².
<Grained Surface Shape>

The surface of the lithographic printing plate support of the present invention has a grained shape in which large pits with a mean aperture diameter of 2 to 10 gm and small pits with a mean aperture diameter of 0.05 to 0.8 μm overlap with each other, and the mean ratio of depth to aperture diameter of the small pits is 0.2 to 0.6.

The large pits with a mean aperture diameter of 2 to 10 μm on the support surface facilitate visual check of the amount of the fountain solution fed to the printing plate surface during printing because the pits have a depth larger than the thickness of the layer of fountain solution. In other words, the water visibility is so improved that the amount of the fountain solution to be fed to the printing plate surface is readily adjustable. If no large pits are present, the asperities on the support surface are reduced to make the surface of the fountain solution smoother and the water visibility poorer accordingly. This is also the case with large pits with too small a mean aperture diameter. If the mean aperture diameter of large pits is too large, it is difficult to balance the sensitivity, the press life and the scumming resistance with one another. The mean aperture diameter of the large pits, as being 2 to 10 μm, is preferably 4 to 8 μm.

A major function of the small pits with a mean aperture diameter of 0.05 to 0.8 μm is to hold the image recording layer by their anchoring effect so as to improve the press life. If the mean aperture diameter of small pits is too large, the press life may be deteriorated because of a reduction in number of the pit edge portions serving as anchors. The small pits with a mean aperture diameter of 0.05 to 0.8 μm also have a role in allowing a uniform layer of fountain solution to be formed and thereby improving the scumming resistance. The mean aperture diameter of the small pits, as being 0.05 to 0.8 μm, is preferably 0.1 to 0.6 μm.

According to the present invention, an excellent press life and an excellent scumming resistance are both obtained by setting the mean ratio of depth to aperture diameter of the small pits at 0.2 to 0.6. If the mean ratio of depth to aperture diameter of the small pits is too small, the press life may be deteriorated. If the mean ratio of depth to aperture diameter of the small pits is too large, the resistance to scumming by leaving and the resistance to scumming by ink spreading may be deteriorated. The mean ratio of depth to aperture diameter of the small pits, as being 0.2 to 0.6, is preferably 0.3 to 0.5.

With respect to the pits which are formed in the surface of the lithographic printing plate support of the present invention, the mean aperture diameter of the large pits, that of the small pits, the standard deviation in aperture diameter of the small pits, and the mean ratio of depth to aperture diameter of the small pits are measured by the following methods.

(1) Mean Aperture Diameter of Large Pits

A scanning electron microscope (SEM) is used to photograph the support surface at 1,000× magnification from right above. In the SEM photograph obtained, 50 large pits with continuous annular edges are extracted to read their diameters as the aperture diameter, and then the mean aperture diameter is calculated.

(2) Mean Aperture Diameter of Small Pits

A scanning electron microscope (SEM) of high resolution is used to photograph the support surface at 50,000× magnification from right above. In the SEM photograph obtained, 50 small pits are extracted to read their diameters as the aperture diameter, and then the mean aperture diameter is calculated.

(3) Mean Ratio of Depth to Aperture Diameter of Small Pits

A scanning electron microscope (SEM) of high resolution is used to photograph the fracture surface of the support at 50,000× magnification. In the SEM photograph obtained, 20 small pits with an aperture diameter of 0.8 μm or less are extracted to read their aperture diameters and depths and find the ratio of depth to aperture diameter of the individual pits, and then the mean ratio is calculated.

In addition, the lithographic printing plate support of the present invention has a surface area difference ΔS⁵⁰ of 20 to 40%. The surface area difference ΔS⁵⁰ is calculated using the above equation (1) from the actual area Sₓ⁵⁰ of a 50 μm square region of the support surface, which area is determined by three-point approximation from the three-dimensional data obtained by measuring the region with an atomic force microscope at 512×512 points, and the geometrically measured area S₀⁵⁰ of the same region.

The surface area difference ΔS⁵⁰ is a factor which indicates the extent of the increase in actual area Sₓ⁵⁰ owing to graining treatment with respect to the geometrically measured area S₀⁵⁰. An increase in surface area difference ΔS⁵⁰ means an increase in area of contact between the support and the image recording layer and, consequently, an improvement in press life. It is effective for the increase in surface area difference ΔS⁵⁰ to form many small recesses or protrusions on the support surface. Suitable methods for forming such recesses or protrusions in the surface include an electrolytic graining treatment with an electrolyte solution chiefly containing hydrochloric acid, and an electrolytic graining treatment with an electrolyte solution chiefly containing nitric acid, which is of high concentration and high temperature. The increase in surface area difference ΔS⁵⁰ is also possible indeed by a mechanical graining treatment or an electrolytic graining treatment with an ordinary electrolyte solution chiefly containing nitric acid, although to a small extent. In the case where the surface area difference ΔS⁵⁰, and the mean ratio of depth to aperture diameter of the small pits as well, should be reduced, chemical etching treatment may suitably be performed after electrolytic graining treatment.

In the present invention, the surface area difference ΔS⁵⁰, as being 20 to 40%, is preferably 25 to 35%. A surface area difference ΔS⁵⁰ within such a range will give an adequate press life.

The surface area difference ΔS⁵⁰ of the lithographic printing plate support of the present invention is determined by the method as below.

i) Measurement of Surface Shape with Atomic Force Microscope

In the present invention, an atomic force microscope (AFM) is used to measure the surface shape so as to obtain the three-dimensional data for the determination of surface area difference ΔS⁵⁰.

Measurement may be carried out under the following conditions: A 1 cm square sample is cut out from the lithographic printing plate support and set on a horizontal sample holder mounted on a piezoelectric scanner. A cantilever is caused to approach the surface of the sample until atomic forces are appreciable and then the surface is scanned in the X and Y directions to acquire the surface asperities of the sample based on the piezoelectric displacement in the Z direction. The piezoelectric scanner used should be capable of scanning 150 μm in the X and Y directions and 10 μm in the Z direction. The cantilever should be that having a resonance frequency of 120 to 150 kHz and a spring constant of 12 to 20 N/m (e.g., SI-DF20 manufactured by Seiko Instruments Inc.; NCH-10 manufactured by NANOSENSORS GmbH & Co. KG; or AC-160TS manufactured by Olympus Corporation), with measurement being carried out in the dynamic force mode (DFM). The three-dimensional data obtained is approximated by the least-squares method to compensate for slight tilting of the sample and determine a reference plane.

Measurement is performed at 512×512 points in a 50 μm square region of the sample surface. The resolution is 1.9 μm in the X and Y directions and 1 nm in the Z direction, and the scan rate is 60 μm/sec.

ii) Calculation of Surface Area Difference ΔS⁵⁰

Using the three-dimensional data (f(x, y)) obtained in i) above, sets of adjacent three points are extracted and the areas of the minimal triangles formed by the individual sets of three points are summated, with the summation being assumed as the actual area Sₓ⁵⁰. The surface area difference ΔS⁵⁰ is calculated from the resulting actual area Sₓ⁵⁰ and the geometrically measured area S₀⁵⁰ using the above equation (1).

In the fabrication of the lithographic printing plate support of the present invention, the alkali metal silicate treatment as will be described later is performed using an aqueous solution of pH 11.5 to 13.5 containing an alkali metal silicate, so as to deposit Si atoms to the support surface in an amount of 3.0 to 15.0 mg/m².

The amount of the deposited Si atoms refers to the weight of the Si atoms per unit area, which is measured by a calibration curve method using an X-ray fluorescence spectrometer (XRF). If this amount is too small, the sensitivity and the scumming resistance may be deteriorated and if too large, the press life may be reduced.

In the present invention, the amount of the Si atoms deposited to the support surface, as being 3.0 to 15.0 mg/m², is preferably 3.5 to 10.0 mg/m² and more preferably 4.0 to 8.0 mg/m², especially 4.5 to 6.5 mg/m².

The reference material for the preparation of calibration curve may be an aqueous sodium silicate solution containing a known amount of Si atoms, which is uniformly dropped onto a region of 30 mm in diameter of the surface of an aluminum plate and then caused to dry. Conditions for X-ray fluorescence spectrometry are exemplified by the following.
X-ray fluorescence spectrometer: RIX3000 manufactured by Rigaku Industrial Corporation.
X-ray tube: Rh.
Spectrum to measure: Si—Kα.
Tube voltage: 50 kV.
Tube current: 50 mA.
Slit: COARSE.
Light-dispersing crystal: RX4.
Detector: F—PC.
Region for spectrometry: circular one of 30 mm in diameter.
Peak position (20): 144.75 deg.
Background (20): 140.70 deg. and 146.85 deg.
Integrating time: 80 sec/sample.

<Aluminum Plate (Rolled Aluminum)>

The aluminum plate to be used in the present invention may be a pure aluminum plate, an alloy plate containing aluminum as the chief ingredient and a trace amount of other element, or a plastic film having aluminum laminated or evaporated onto it. The alloy plate contains one or more elements selected from among those set forth in the periodic table, each in an amount of 0.001 to 1.5 wt %.

Typical elements other than aluminum which are present in an aluminum alloy include silicon, iron, nickel, manganese, copper, magnesium, chromium, zinc, bismuth, titanium, and vanadium. Generally used alloys are those of known compositions described in the 4^{th} edition of Aluminum Handbook (the Light Metal Association (Japan), 1990), such as JIS A1050 material, JIS A3005 material, JIS A1100 material, JIS A3004 material and International Alloy Designation 3103A material, or alloys obtained by adding 5 wt % or less of magnesium to such materials in order to increase the tensile strength.

The aluminum plate to be used in the present invention may also be an aluminum plate obtained by rolling an ingot which is made from, for instance, recycled scrap beverage cans and in which impurities abound.

The fabrication method as will be described later allows a uniformly grained shape (uniform honeycomb pits) after an electrochemical graining treatment in an aqueous hydrochloric acid solution, even if such trace elements as above abound in the aluminum plate.

In the present invention, an aluminum plate produced by a direct-chill (DC) casting method from which intermediate annealing treatment and/or soaking treatment is omitted, and that produced by a continuous casting method from which intermediate annealing treatment is omitted are also usable.

The thickness of the aluminum plate is preferably 0.05 to 0.8 mm and more preferably 0.1 to 0.6 mm.

In the fabrication of the lithographic printing plate support of the present invention, it is preferable to obtain the support by subjecting such an aluminum plate as described above to surface graining treatment involving an electrochemical graining treatment in an aqueous solution containing hydrochloric acid. In that case, the surface treatment may include various additional treatments. Furthermore, an alloying ingredient of the aluminum plate should be dissolved in the treatment solutions which are used in various processes employed in the present invention, and the treatment solutions may previously contain the alloying ingredient of the aluminum plate. It is rather preferred that such an alloying ingredient is added to the treatment solutions so as to put the solutions into a stationary state before use for treatment.

In the present invention, graining may be carried out by performing the undermentioned treatments in combination. Preferably, alkali etching treatment or desmutting treatment is performed before electrochemical graining treatment. It is also preferable to perform alkali etching treatment and desmutting treatment in this order before electrochemical graining treatment. Likewise, alkali etching treatment or desmutting treatment is preferably performed after electrochemical graining treatment. It is also preferable to perform alkali etching treatment and desmutting treatment in this order after electrochemical graining treatment. In fact, alkali etching treatment may not be performed after electrochemical graining treatment.

In the present invention, it is also preferable that such treatments as above are preceded by mechanical graining treatment. Any electrochemical graining treatment may be performed two times or more. It is also preferable that the above treatments are followed by sealing treatment, hydrophilizing treatment, and so forth.

In a preferred embodiment of the present invention, alkali etching treatment, desmutting treatment, electrochemical graining treatment in an aqueous hydrochloric acid solution, alkali etching treatment and/or desmutting treatment, anodizing treatment, and hydrophilizing treatment are particularly performed in this order in the surface treatment.

In that case, it is preferable to use an alkali metal silicate in the hydrophilizing treatment. It is also preferable that the surface treatment involves mechanical graining treatment to be performed before the first alkali etching treatment.

The following description will give a full detail of mechanical graining treatment, alkali etching treatment, desmutting treatment, electrochemical graining treatment, anodizing treatment, sealing treatment, and hydrophilizing treatment.

<Mechanical Graining Treatment>

In the present invention, mechanical graining treatment is preferably performed before electrochemical graining treatments. Mechanical graining increases the surface area of an aluminum plate.

Before brush graining, an aluminum plate is degreased as desired with a surfactant, an organic solvent, an aqueous alkali solution or the like in order to remove a rolling oil from the plate surface. Degreasing treatment may be omitted if the rolling oil remains on the surface in a small amount.

Subsequently, a brush or brushes of one type, or of at least two types with different bristle diameters, are used to perform brush graining on the aluminum plate while feeding its surface with an abrasive slurry.

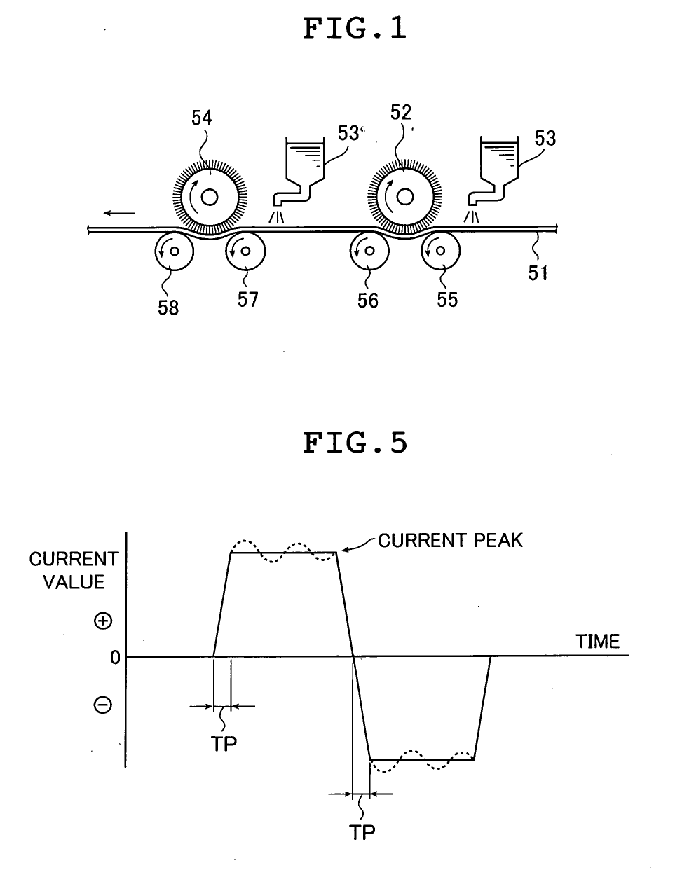

Mechanical graining treatment is described in JP 6-135175 A and JP 50-40047 B in detail. In the brush graining as above, the brush used first is referred to as the first brush and that used last as the second brush. FIG. 1 shows an aluminum plate 51, roller brushes 52 and 54, an abrasive slurry 53, and support rollers 55, 56, 57 and 58. Upon graining, the roller brushes 52 and 54 are located on one side of the aluminum plate 51 and the support rollers in pairs, 55 and 56 as well as 57 and 58, are located on the other side as shown in FIG. 1. Each pair of support rollers is so arranged that the two support rollers 55 and 56 or 57 and 58 may have the shortest distance between their external surfaces that is less than the outer diameter of the relevant roller brush 52 or 54. It is preferable that the aluminum plate 51 is caused to travel at a constant speed while pressed by the roller brushes 52 and 54 a bit down into the spaces between the two support rollers 55 and 56 as well as 57 and 58, respectively, and the surface of the traveling aluminum plate 51 is grained by feeding the abrasive slurry 53 onto the plate and rotating the roller brushes 52 and 54.

Brushes suitable for use in the present invention include: a brush in which bristles made of such a material as nylon, polypropylene, animal hair and steel wire are set in a roller-shaped block with a uniform bristle length and homogeneous bristle distribution; a brush in which bristle staples are inserted into the small holes provided on a roller-shaped block; and a brush of a channel-roller type. It is particularly preferred that the bristle material is nylon and the set bristles have a length of 10 to 200 mm. Preferably, 30 to 1,000 bristles and more preferably 50 to 300 bristles per square centimeter are set so as to make a roller brush.

The bristle diameter of the brush or brushes used is preferably 0.24 to 0.83 mm and more preferably 0.295 to 0.72 mm. It is preferred that the brush bristles are circular in cross section. If the bristle diameter is smaller than 0.24 mm, the scumming resistance may be deteriorated in a region of shadows, and if larger than 0.83 mm, the scumming resistance may be deteriorated on a blanket. The preferred material for bristles is nylon, with nylon 6, nylon 6.6, nylon 6.10 and so forth being usable, and the most preferred is nylon 6.10 in terms of tensile strength, wear resistance, dimensional stability during water absorption, flexural strength, heat resistance, recovery properties, and other properties.

The number of brushes is preferably 1 to 10, and more preferably 1 to 6. In this connection, roller brushes which are different from one another in bristle diameter may be used in combination, as described in JP 6-135175 A.

It is preferable that a roller brush is rotated at any speed within a range of 100 to 500 rpm. The roller used as a support roller should have a rubber or metallic surface and be well kept straight. The rotational direction of a roller brush is preferably the same as the direction in which an aluminum plate travels as shown in FIG. 1, although some of multiple roller brushes used at a time may be rotated in the reverse direction. The indentation of a brush is preferably controlled as the load on the motor for rotatively driving the brush. It is preferred to control the load so that the power consumption of the motor may be 1.0 to 15 kW, especially 2 to 10 kW.

In the present invention, a support which is excellent in all of water wettability, water receptivity and adhesion is obtained advantageously by performing a treatment with a brush having a smaller bristle diameter within the above range after a graining treatment with a brush having a larger bristle diameter within the same range. With such a support, flat shadows resulting from the fountain solution shortness are avoided so that the water latitude is wide, and scumming is hardly generated. Moreover, the adhesion to the image recording layer is not deteriorated.

The abrasive slurry to be used in the present invention is preferably prepared by dispersing such an abrasive as silica sand, aluminum hydroxide, alumina powder, volcanic ash, pumice, carborundum and emery having a mean particle diameter of 1 to 50 μm (preferably 20 to 45 μm) in water to such an extent that the resulting slurry may have a specific gravity of 1.05 to 1.3. The mean particle diameter is defined as the particle diameter under which the cumulative ratio falls to 50% when the cumulative frequency is found with respect to the volume ratio of particles with a given diameter to the total abrasive in a slurry.

It is preferred that mechanical graining treatment is so performed as to bring about a center line-mean roughness (Rₐ) of 0.3 to 1.0 μm.

Naturally, mechanical graining may also be carried out by blasting with an abrasive slurry, by the use of a wire brush, or by transferring the surface shape of a reduction roll with asperities provided thereon to an aluminum plate. Other mechanical graining methods are described in JP 55-074898 A, JP 61-162351 A, JP 63-104889 A, and so forth.

It is preferable to chemically etch the surface of an aluminum plate after the plate is subjected to the brush graining as described above. This chemical etching treatment has a function of removing abrasives, aluminum scraps and so forth digging into the surface of the aluminum plate subjected to the brush graining treatment, making it possible to subsequently achieve a more uniform and effective electrochemical graining.

<Chemical Etching Treatment in Aqueous Alkali Solution (First Alkali Etching Treatment)>

In alkali etching treatment, the aluminum plate as described before is chemically etched by bringing it into contact with an alkali solution. The alkali etching treatment is preferably performed for the purpose of removing a rolling oil, contaminants and a natural oxide film from the surface of the aluminum plate (rolled aluminum) if mechanical graining treatment is not performed, or dissolving the edge portions of the asperities provided on the plate surface by mechanical graining treatment and thereby allowing a mild undulation on the surface.

Illustrative examples of the method of bringing the aluminum plate into contact with an alkali solution include a method in which the aluminum plate is caused to pass through a tank filled with an alkali solution, a method in which the aluminum plate is immersed in an alkali solution in a tank, and a method in which an alkali solution is sprayed onto the surface of the aluminum plate.

Such a chemical etching method is described in U.S. Pat. No. 3,834,398 in detail. In the method, immersion in a solution capable of dissolving aluminum or, to be more specific, an aqueous solution of an alkali is performed.

Examples of the alkali include sodium hydroxide, potassium hydroxide, sodium tertiary phosphate, potassium tertiary phosphate, sodium aluminate, sodium metasilicate, and sodium carbonate. Use of an aqueous solution of a base allows a higher etching rate.

It is preferable that chemical etching is carried out by performing a treatment with a 0.05 to 40 wt % aqueous solution of such an alkali as above at a solution temperature of 40 to 100° C. for 5 to 300 seconds. More preferably, the concentration of the aqueous alkali solution is 1 to 30 wt %, and the solution may contain 0 to 10 wt % of not only aluminum but also any alloying ingredient present in the aluminum plate. An aqueous solution chiefly containing caustic soda is more preferable as the aqueous alkali solution. It is more preferable that the treatment is performed at a solution temperature ranging from an ordinary temperature to 95° C. for 1 to 120 seconds.

In order not to bring the treatment solution in the next process, it is desirable to remove the solution from the aluminum plate with nip rollers and rinse the plate with a spray of water after the completion of etching treatment.

The amount of the aluminum plate chemically etched is preferably 0.001 to 30 g/m² and more preferably 1 to 15 g/m², especially 3 to 12 g/m², as the amount of the plate dissolved on one side.

<Acid Etching Treatment>

Acid etching treatment, as a treatment in which an aluminum plate is chemically etched in an aqueous acid solution, is preferably performed after the electrochemical graining treatment as described before. It is also preferable to perform acid etching treatment after the alkali etching treatment as above if the alkali etching treatment is performed before and/or after the electrochemical graining treatment.

The acid etching treatment performed on the aluminum plate after the alkali etching treatment as above makes it possible to remove intermetallic compounds containing silicon, or Si as a simple substance, on the aluminum plate surface, so that the anodized layer formed in a subsequent anodizing treatment gets rid of defects. As a consequence, a troublesome staining of non-image areas with ink dots, which leads to so-called dusty scumming, can be prevented during printing.

Examples of the aqueous acid solution for use in acid etching treatment include an aqueous solution containing phosphoric acid, nitric acid, sulfuric acid, chromic acid, hydrochloric acid, or a mixed acid comprising at least two such acids. Particularly preferred is an aqueous sulfuric acid solution. The concentration of the aqueous acid solution is preferably 50 to 500 g/L. The aqueous acid solution may contain not only aluminum but also any alloying ingredient present in the aluminum plate.

It is preferable that acid etching treatment is performed at a solution temperature of 60 to 90° C., more preferably 70 to 80° C., for 1 to 10 seconds. In that case, the amount of the aluminum plate dissolved is preferably 0.001 to 0.2 g/m². It is also preferable that the acid concentration, for instance, sulfuric acid concentration and the aluminum ion concentration are each selected from among those which do not cause the crystallization at an ordinary temperature. The preferred aluminum ion concentration is 0.1 to 50 g/L and the more preferred is 5 to 15 g/L.

In order not to bring the treatment solution in the next process, it is desirable to remove the solution from the aluminum plate with nip rollers and rinse the plate with a spray of water after the completion of acid etching treatment.

<Desmutting Treatment in Aqueous Acid Solution (First Desmutting Treatment)>

As a rule, the aluminum surface chemically etched using an aqueous alkali solution suffers from smut, so that it is preferable that the chemical etching treatment in an aqueous alkali solution is followed by a desmutting treatment with phosphoric acid, nitric acid, sulfuric acid, chromic acid, hydrochloric acid, or a mixed acid comprising at least two such acids. Desmutting is carried out by bringing the aluminum plate into contact with an aqueous acid solution.

The concentration of the aqueous acid solution is preferably 0.5 to 60 wt %. In the solution, 0 to 5 wt % of not only aluminum but also any alloying ingredient present in the aluminum plate may be dissolved.

It is rather preferred that the wastewater from electrochemical graining treatment or from anodizing treatment is used as the desmutting treatment solution.

The treatment is performed at a solution temperature ranging from an ordinary temperature to 95° C., with a solution temperature of 30 to 70° C. being preferable. The treatment time is preferably 1 to 120 seconds and more preferably 1 to 5 seconds. In order not to bring the treatment solution in the next process, it is desirable to remove the solution from the aluminum plate with nip rollers and rinse the plate with a spray of water after the completion of desmutting treatment. The solution removal with nip rollers and rinsing with a spray of water can be omitted if the desmutting treatment solution is of the same kind or the same composition as the solution used in the next process.

Desmutting in an aqueous acid solution may not be performed before electrochemical graining treatment if an apparatus for use in the electrochemical graining treatment is provided with an auxiliary anode cell for the prevention of electrode dissolution and the control of grained shapes, which is positioned before the cell in which the electrochemical graining treatment is performed by passing alternating current through the aluminum plate.

<Electrochemical Graining Treatment>

The electrochemical graining treatment to be performed in the present invention is characterized by the electrochemical graining in an aqueous solution containing hydrochloric acid (hereafter also referred to as “aqueous solution chiefly containing hydrochloric acid”).

The objects of the present invention can be achieved by performing such an electrochemical graining treatment under specified conditions, and anodizing treatment, and further performing, as required, hydrophilizing treatment, mechanical graining treatment and various other surface treatments as herein described.

Electrochemical graining treatment may be performed two times or more. It is also possible to perform electrochemical graining treatment in an aqueous solution chiefly containing nitric acid before or after performing in an aqueous solution chiefly containing hydrochloric acid.

The following are particular descriptions on electrochemical graining treatment.

(1) Aqueous Solution Chiefly Containing Hydrochloric Acid

The aqueous solution chiefly containing hydrochloric acid that is to be used in the present invention may be any of such solutions used in the conventional electrochemical graining treatment employing direct current or alternating current, and a usable solution is prepared by adding at least one chloride compound containing a chloride ion such as aluminum chloride, sodium chloride and ammonium chloride or at least one nitrate compound containing a nitrate ion such as aluminum nitrate, sodium nitrate and ammonium nitrate to an aqueous hydrochloric acid solution with a 1 to 30 g/L concentration at a level ranging from 1 g/L to saturation. A compound which forms a complex with copper may also be added in an amount of 1 to 200 g/L. In the aqueous solution chiefly containing hydrochloric acid, any alloying metal present in the aluminum plate, including iron, copper, manganese, nickel, titanium, magnesium and silicon, may be dissolved. It is also possible to add hypochlorous acid or hydrogen peroxide to the solution in an amount of 1 to 100 g/L.

Preferably, 10 to 300 g/L of an aluminum salt (aluminum chloride: AlCl₃.6H₂O) is added to an aqueous hydrochloric acid solution with a hydrochloric acid.content of 1 to 30 g/L at a solution temperature of 15 to 50° C. so as to cause the solution to have an aluminum ion concentration of 1 to 30 g/L. The electrochemical graining treatment performed by using such an aqueous hydrochloric acid solution will bring about a uniform surface shape, avoid nonuniform graining even if a rolled aluminum plate of low purity (aluminum plate containing an alloying ingredient at a higher rate or in an uncontrolled state) is used, and, consequently, allow both a good press life and a high printing performance (scumming resistance) when a lithographic printing plate is prepared.

It is more preferable that the aqueous hydrochloric acid solution contains 5 to 20 g/L, especially 8 to 15 g/L, of hydrochloric acid. A hydrochloric acid concentration within such a range will allow the surface area difference ΔS⁵⁰ and the mean ratio of depth to aperture diameter of the small pits to be increased.

The amount of the aluminum chloride hexahydrate added is preferably 10 to 300 g/L and more preferably 50 to 200 g/L, especially 80 to 150 g/L.

The aluminum ion concentration of the aqueous hydrochloric acid solution after the addition of aluminum chloride hexahydrate thereto is preferably 1 to 30 g/L and more preferably 5 to 20 g/L, especially 8 to 15 g/L.

With respect to the substances to be added to an aqueous solution chiefly containing hydrochloric acid, apparatus, power sources, current densities, flow rates, and temperatures, those which are used for the conventional electrochemical graining can be used. The power source for use in electrochemical graining may be of either a DC or AC type, although an AC power source is preferable. The amount of electricity to be used for the anodic reaction on the aluminum plate during electrochemical graining treatment in an aqueous solution chiefly containing hydrochloric acid can be so selected as to be 10 to 1,000 C/dm², preferably 200 to 800 C/dm² and more preferably 300 to 600 C/dm² at the end of the electrochemical graining treatment. Large pits with a mean aperture diameter of 2 to 10 μm can be formed by controlling the amount of electricity.

(2) Aqueous Solution Chiefly Containing Nitric Acid

The aqueous solution chiefly containing nitric acid that is to be used in the present invention may be any of such solutions used in the conventional electrochemical graining treatment employing direct current or alternating current, and a usable solution is prepared by adding at least one chloride compound containing a chloride ion such as aluminum chloride, sodium chloride and ammonium chloride or at least one nitrate compound containing a nitrate ion such as aluminum nitrate, sodium nitrate and ammonium nitrate to an aqueous nitric acid solution with a 1 to 100 g/L concentration at a level ranging from 1 g/L to saturation. A compound which forms a complex with copper may also be added in an amount of 1 to 200 g/L. In the aqueous solution chiefly containing nitric acid, any alloying metal present in the aluminum plate, including iron, copper, manganese, nickel, titanium, magnesium and silicon, may be dissolved. It is also possible to add hypochlorous acid or hydrogen peroxide to the solution in an amount of 1 to 100 g/L.

Preferably, an aluminum salt (aluminum nitrate) is added to an aqueous nitric acid solution with a nitric acid content of 5 to 15 g/L at a solution temperature of 15 to 90° C. so as to cause the solution to have an aluminum ion concentration of 3 to 50 g/L. With respect to the substances to be added to an aqueous solution chiefly containing nitric acid, apparatus, power sources, current densities, flow rates, and temperatures, those which are used for the conventional electrochemical graining can be used. The power source for use in electrochemical graining may be of either a DC or AC type, although an AC power source is preferable. The amount of electricity to be used for the anodic reaction on the aluminum plate during electrochemical graining treatment in an aqueous solution chiefly containing nitric acid can be so selected as to be 10 to 1,000 C/dm², preferably 100 to 500 C/dm² and more preferably 150 to 300 C/dm² at the end of the electrochemical graining treatment.

(3) Electrochemical Graining

Electrochemical graining treatment is considered as a graining treatment which is electrochemically performed by applying direct current or alternating current between an aluminum plate and the electrode opposite to the plate in an aqueous acid solution. In the present invention, alternating current is preferably applied and the alternating current may be of any type, a single-phase, two-phase or three-phase type, for instance. It is also possible to use a current which is obtained by superposing alternating current and direct current upon each other.

Any known electrolytic cell for use in surface treatment, including those of vertical, flat, and radial types, is usable for electrochemical graining. Electrochemical graining treatment may be performed using a plurality of such electrolytic cells. Electrochemical graining treatment may also be performed repeatedly while interposing the etching treatment in an aqueous acid or alkali solution, the desmutting treatment in an aqueous acid solution, a cathodic electrolysis treatment to be performed on the aluminum plate in an aqueous acid solution or aqueous solution of a neutral salt, and so forth.

a) System of Power Supply to Aluminum Plate

The aluminum plate may be supplied with electric power by the direct power supplying system in which a conductor roll is used, or the via-solution power supplying system (indirect power supplying system) in which no conductor roll is used. The electrolyte solution passing through an electrolytic cell may flow in the cell parallel or counter to the movement of the aluminum plate in web form. One electrolytic cell can be connected with one AC power source or more. When the indirect power supplying system is employed, the ratio between the amount of electricity applied to the aluminum plate when it serves as the anode and that applied to the aluminum plate when it serves as the cathode is preferably adjusted by the method as described in JP 6-37716 B or JP 5-42520 B using an auxiliary anode. More preferably, the current passing through the auxiliary anode is controlled with rectifying devices such as thyristors, diodes and GTOs. By using the method as described in JP 6-37716 B, it is readily possible to control the amount of electricity (current value) of the alternating current applied. to the aluminum plate surface opposite to a principal carbon electrode, on which electrochemical graining reaction takes place, not only when the aluminum plate serves as the anode but also as the cathode. The method is very advantageous also in terms of the cost of power source construction because of little. influence of the asymmetric magnetization of a transformer.

When electrochemical graining is performed using a sinusoidal wave current, the current value is controlled by using a transformer, a variable induction regulator and so forth in combination to allow feedback to the variable induction regulator on the value of the current used for electrolysis. Such a control of the current value may be combined with the method as described in JP 55-25381 A in which phase control is carried out with a thyristor.

In electrochemical graining treatment, current is liable to be nonuniform unless the distance between the aluminum plate and an electrode as well as the flow rate of the solution are kept constant. A nonuniform current will bring about the aluminum surface grained nonuniformly and make the aluminum plate inadequate as a lithographic printing plate support. In order to avoid such problems, a solution feeding nozzle can be used which has a solution reservoir in its interior, and is provided with some 1 to 5 mm slits for solution spouting which are arranged in a line across the aluminum web. It is preferable to provide a plurality of solution reservoirs and fit the piping connecting the reservoirs to the respective slits with valves and flowmeters for controlling the amount of the solution spouted from the individual slits.

The distance between the aluminum web and an electrode is preferably 5 to 100 mm and more preferably 8 to 15 mm. In order to keep the distance constant, the method as described in JP 61-30036 B is used, in which a web is caused to travel while coming under static pressure into contact with a face which allows the traveling web to slide. Alternatively, such a method as described in JP 8-300843 A may be used, in which the distance between an electrode and an aluminum plate is kept constant with a roller of large diameter.

When the direct power supplying system is employed, it is preferable to perform electrochemical graining treatment in the apparatus as described in JP 56-123400 A using such a conductor roll as described in JP 58-177441 A. The conductor roll may be positioned either on the upper or lower side of the aluminum web, although it is rather preferred to position the conductor roll on the upper side of the aluminum plate and press the roll against the plate by means of a nipping device. The length along which the aluminum plate comes into contact with the conductor roll is preferably 1 to 300 mm in the moving direction of the aluminum plate. The path roll located on the other side of the aluminum plate and opposed to the conductor roll is preferably made of rubber. The pressure exerted upon pressing and the hardness of a rubber roll are arbitrarily set on condition that no arc spots are generated. The conductor roll provided on the upper side of the aluminum plate is easy to replace and check up. The conductor roll is suitably energized at its end through a power supply brush adapted to slide on a rotating body.

In order to prevent the generation of arc spots, it is preferable that the conductor roll pressed against the aluminum plate is always cooled with an electrolyte solution of the same composition and temperature as the electrolyte solution used for electrochemical graining. Foreign matter in an electrolyte solution is liable to cause arc spots, so that it is preferable to wind a filter cloth around a spray for use in cooling, to insert a fine mesh filter in the piping upstream of a spray line for cooling, and so forth.

b) Electrochemical Graining by Using Alternating Current

The AC power waveform used in electrochemical graining may, for instance, be a sinusoidal, square, trapezoidal or triangular waveform, although the preferred is a square or trapezoidal waveform, especially a trapezoidal one. The frequency is preferably 0.1 to 500 Hz and more preferably 40 to 120 Hz, especially 45 to 65 Hz.

When a trapezoidal waveform is used, the time tp for the transition of current from zero to peak is preferably 0.1 to 2 msec and more preferably 0.2 to 1.5 msec. If the time tp is less than 0.1 msec, a large source voltage is required upon the rise of the current waveform under the influence of the impedance of a power supply circuit, so that the cost of power supply equipment goes up. If the time tp is more than 2 msec, uniform graining is hard to achieve due to an increasing affection of the trace ingredients in the electrolyte solution. The ratio of the time ta for the anodic reaction on the aluminum plate to the cycle T of the alternating current used for electrochemical graining, ta/T (herein referred to as “duty”), that defines the cycle of the alternating current, is preferably 0.33 to 0.66 and more preferably 0.45 to 0.55, especially 0.5.

During the cathodic reaction on the aluminum plate, an oxide film composed primarily of aluminum hydroxide is formed on the plate surface and the film happens to be further dissolved or damaged. In that case, during the subsequent anodic reaction on the aluminum plate, pitting reaction will start in the spots where the oxide film has been dissolved or damaged. Accordingly, selection of the duty for the alternating current is of particular importance to a uniform electrolytic graining treatment.

With respect to the amount of electricity applied to the aluminum plate opposite to a principal electrode, the ratio of the amount of electricity Q_{c} at the time of cathodic reaction on the aluminum plate to the amount of electricity Qₐ at the time of anodic reaction, Q_{c}/Qₐ, is 0.9 to 1.0, preferably 0.92 to 0.98 and more preferably 0.94 to 0.96. With a ratio Q_{c}/Qₐ within such a range, nonuniform graining is avoided, and a good press life and a high printing performance (scumming resistance) are both attained when a lithographic printing plate is prepared. On the other hand, a ratio Q_{c}/Qₐ of over 1.0 may cause an electrode to be dissolved. The ratio Q_{c}/Qₐ can be controlled by controlling the voltage generated by a power source.

When electrolytic graining treatment is performed by using an AC electrolytic cell having an auxiliary electrode for shunting the anode current passing through a principal electrode, the ratio Q_{c}/Qₐ can be controlled by controlling the current value of the anode current portion shunted into the auxiliary electrode, as described in JP 60-43500 A and JP 1-52098 A.

The current density is preferably 10 to 200 A/dm² at trapezoidal-wave peaks, both on the anode cycle side and cathode cycle side of the current. Representing the current density on the anode and cathode cycle sides by Iₐ and I_{c}, respectively, the ratio Iₐ/I_{c} is preferably 0.5 to 3.

In the present invention, any known electrolytic cell for use in surface treatment, including those of vertical, flat, and radial types, is usable for electrochemical graining with alternating current, although it is rather preferred to use such a radial-type electrolytic cell as described in JP 5-195300 A, or a flat-type one. It is preferable that carbon is used for a principal electrode and ferrite for an auxiliary anode.

It is also suitable to use an apparatus for electrolytic graining treatment which is provided with a plurality of AC electrolytic cells arranged in series.

The electrolytic cell having an auxiliary anode may be positioned before or after the electrolytic cell having a principal electrode. Particularly when electrochemical graining is based on the use of hydrochloric acid, however, it is preferred to position the electrolytic cell having an auxiliary electrode before the electrolytic cell having a principal electrode because a more uniform graining is allowed.

In addition, if the distance between the inlet (solution level) of the electrolytic cell having an auxiliary electrode and the inlet (solution level) of the electrolytic cell having a principal electrode is too long, intermetallic compounds in the aluminum plate are dissolved due to the chemical dissolution reaction with hydrochloric acid to leave deep holes, which will make the thickness of image recording layer increased partially and thus result in the nonuniformity of printing. For that reason, it is preferable that the time to move the aluminum plate from the inlet (solution level) of the electrolytic cell having an auxiliary electrode to the inlet (solution level) of the electrolytic cell having a principal electrode is 3 seconds or less.

In the electrolytic graining treatment in which one or at least two AC electrolytic cells are used, it is preferable to define the idle period one time or more, for which period alternating current is caused not to flow between the aluminum plate located between the principal electrodes in one electrolytic cell which are connected with the power supply terminals of different polarities, respectively, and these principal electrodes, and to set the idle period at 0.001 to 0.6 seconds in length. In that case, honeycomb pits can be formed uniformly over the entire surface of the aluminum plate. The idle period is more preferably 0.005 to 0.55 seconds, especially 0.01 to 0.5 seconds.

When two or more AC electrolytic cells arranged in series are used, the period of time for which the aluminum plate is located between one electrolytic cell and another, and alternating current does not pass through the plate is preferably 0.001 to 20 seconds and more preferably 0.1 to 15 seconds, especially 1 to 12 seconds.

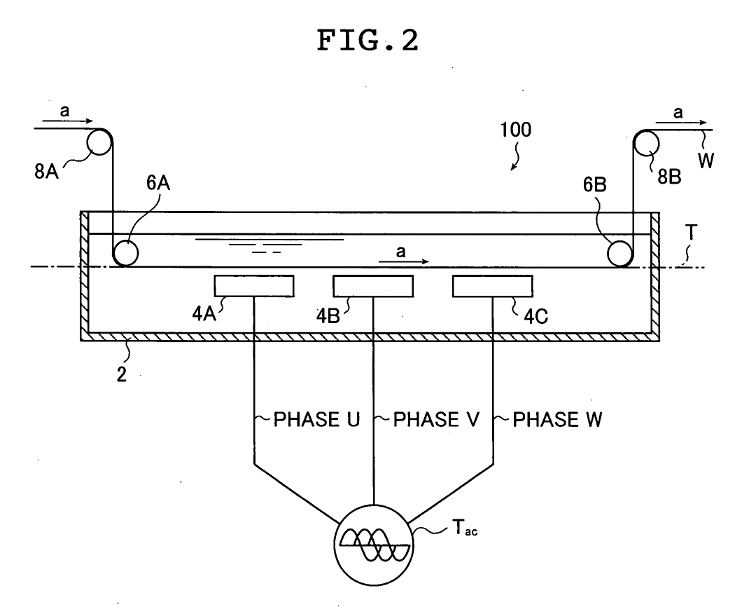

FIG. 2 is a schematic cross-sectional view of an example of the electrolytic graining treatment apparatus provided with a flat-type AC electrolytic cell that is suitably used in the present invention. FIG. 2 shows an electrolytic graining treatment apparatus 100 including an AC electrolytic cell 2, principal electrodes 4A, 4B and 4C, feed rollers 6a and 6B, a guide-in roller 8A, and a guide-out roller 8B. The electrolytic graining treatment apparatus 100 is an apparatus for subjecting an aluminum web W to electrolytic graining treatment by applying a three-phase alternating current (hereafter also referred to as “three-phase AC electric current”) to the web while causing the web to travel in an almost horizontal direction.

In the electrolytic graining treatment apparatus 100, the AC electrolytic cell 2 is in the form of a shallow box with an open top, which extends along the traveling direction a of the aluminum web W. The three principal electrodes 4A, 4B and 4C, each in a planar shape, are arranged in the vicinity of the bottom of the AC electrolytic cell 2, along the traveling direction a and parallel to the traveling plane T as the traveling path of the aluminum web W. The feed rollers 6A and 6B are positioned inside the AC electrolytic cell 2 in the vicinity of the end on the upstream side in the traveling direction a (hereafter referred to merely as “upstream side”) and in the vicinity of the end on the downstream side in the traveling direction a (hereafter referred to merely as “downstream side”), respectively, so as to cause the aluminum web W to travel inside the AC electrolytic cell 2. The guide-in roller 8A is positioned above the AC electrolytic cell 2 on the upstream side so as to guide the aluminum web W to the interior of the electrolytic cell 2. The guide-out roller 8B is positioned above the AC electrolytic cell 2 on the downstream side so as to guide the aluminum web W having passed through the interior of the electrolytic cell 2 to the exterior thereof. The AC electrolytic cell 2 is stored with the aqueous acid solution as described before.

The principal electrodes 4A, 4B and 4C are connected with a phase U terminal, a phase V terminal and a phase W terminal of an AC power source T_{ac} generating a three-phase alternating current, respectively. Accordingly, the alternating currents applied to the principal electrodes 4A, 4B and 4C, respectively, are 120° out of phase with one another.

The electrolytic graining treatment apparatus 100 operates as follows.

The aluminum web W is guided by the guide-in roller 8A to the interior of the AC electrolytic cell 2, and caused by the feed rollers 6A and 6B to travel in the traveling direction a at a constant speed.

In the interior of the AC electrolytic cell 2, the aluminum web W travels parallel to the principal electrodes 4A, 4B and 4C, through which, meanwhile, alternating current is applied to the web. As a result, anodic reaction and cathodic reaction alternately take place on the aluminum web W, with honeycomb pits being chiefly formed during the anodic reaction and a film of aluminum hydroxide during the cathodic reaction, and the web surface is thus grained.

Since the alternating currents applied to the principal electrodes 4A, 4B and 4C, respectively, are 120° out of phase with one another as described above, anodic and cathodic reactions are repeated on the principal electrode 4B at a phase (phase V) lagging by 120° behind the phase (phase U) on the principal electrode 4A, and repeated on the principal electrode 4C at a phase (phase W) lagging by 120° behind the phase on the principal electrode 4B.

On the aluminum web W, accordingly, anodic and cathodic reactions are repeated three times as more frequently as the case of applying a single-phase alternating waveform current of the same frequency as the three-phase current, so that chatter marks as the stripes extending across the web are hardly made even if electrolytic graining treatment is performed at higher traveling speed and current density.

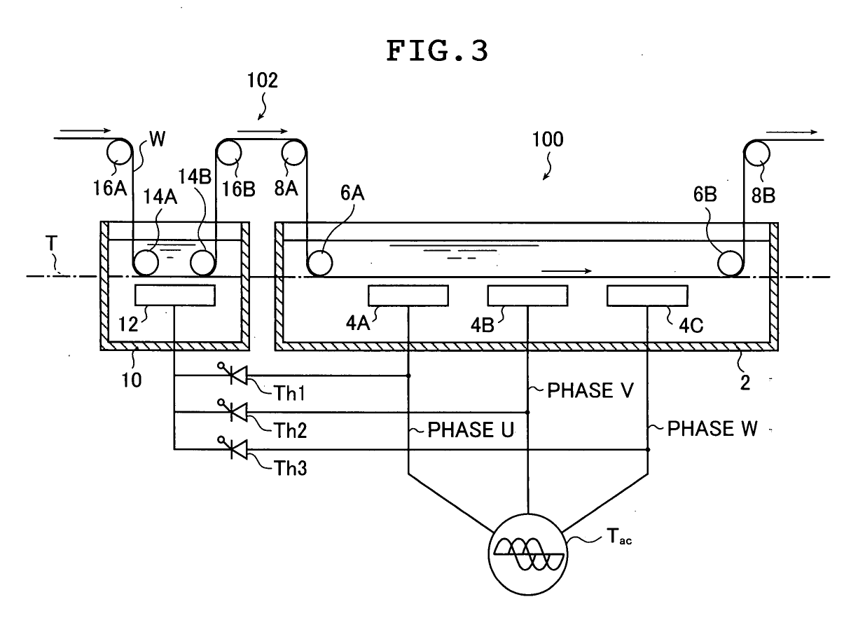

FIG. 3 is a schematic cross-sectional view of another example of the electrolytic graining treatment apparatus provided with a flat-type AC electrolytic cell that is suitably used in the present invention. In FIG. 3 showing the same elements as shown in FIG. 2 with the same reference characters, an electrolytic graining treatment apparatus 102 includes an auxiliary electrolytic cell 10, an auxiliary electrode 12, feed rollers 14A and 14B, a guide-in roller 16A, a guide-out roller 16B, and thyristors Th1, Th2 and Th3.

The electrolytic graining treatment apparatus 102 has such a configuration that the electrolytic graining treatment apparatus 100 as described above is further provided with the auxiliary electrolytic cell 10 positioned before the AC electrolytic cell 2.

The auxiliary electrolytic cell 10 is in the form of a box with an open top, and the auxiliary electrode 12 in a planar shape is so arranged in the vicinity of the bottom of the electrolytic cell 10 as to be parallel to the traveling plane T of the aluminum web W.

The feed rollers 14A and 14B are positioned in the vicinity of the upstream-side and downstream-side walls of the auxiliary electrolytic cell 10, respectively, so as to cause the aluminum web W to travel above the auxiliary electrode 12. The guide-in roller 16A is positioned above the auxiliary electrolytic cell 10 on the upstream side so as to guide the aluminum web W to the interior of the electrolytic cell 10. The guide-out roller 16B is positioned above the auxiliary electrolytic cell 10 on the downstream side so as to guide the aluminum web W having passed through the interior of the electrolytic cell 10 to the exterior thereof. The auxiliary electrolytic cell 10 is stored with the aqueous acid solution as described before.

The phase U terminal, phase V terminal and phase W terminal of the AC power source T_{ac} are connected to the auxiliary electrode 12 via the thyristors Th1, Th2 and Th3, respectively. Each of the thyristors Th1, Th2 and Th3 is so connected that electric current may flow from the AC power source T_{ac} to the auxiliary electrode 12 when the thyristor is ignited. Since an anode current thus passes through the auxiliary electrode 12 whichever thyristor, Th1, Th2 or Th3, is ignited, the current value of the anode current passing through the auxiliary electrode 12 and, consequently, the value of Q_{c}/Qₐ can be controlled by the phase control of the thyristors Th1, Th2 and Th3.

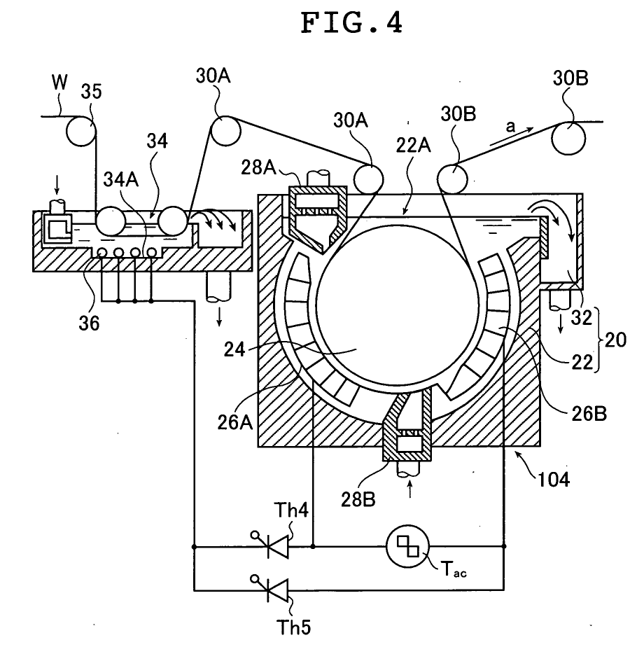

FIG. 4 is a schematic cross-sectional view of an example of the electrolytic graining treatment apparatus provided with a radial-type AC electrolytic cell that is suitably used in the present invention. FIG. 4 shows an AC electrolytic cell 20, principal electrodes 26A and 26B, an auxiliary electrolytic cell 34, an upstream-side guide roller 35, auxiliary electrodes 36, an AC electrolytic cell body 22, an opening 22A, a feed roller 24, solution feeding nozzles 28A and 28B, upstream-side guide rollers 30A, downstream-side guide rollers 30B, an overflow reservoir 32, the bottom 34A of the auxiliary electrolytic cell 34, an electrolytic graining treatment apparatus 104, and thyristors Th4 and Th5.

The electrolytic graining treatment apparatus 104 includes the AC electrolytic cell 20 having the AC electrolytic cell body 22 which is stored with an aqueous acid solution, and also includes the feed roller 24 so arranged in the cell body 22 as to be rotatable about a horizontal axis. The feed roller 24 causes an aluminum web W to travel in a traveling direction a, from the left to the right in the figure. The cell body 22 is stored with the aqueous acid solution as described before.

The inner wall of the AC electrolytic cell body 22 is formed almost cylindrically so as to surround the feed roller 24, and the principal electrodes 26A and 26B in a semicylindrical shape are provided on the inner wall, with the feed roller 24 being sandwiched between them. The principal electrodes 26A and 26B are each divided into a plurality of small electrodes, and an insulating spacer is interposed between each two small electrodes. The small electrodes may be formed with graphite or metal, while the spacers may be formed with polyvinyl chloride. The thickness of the spacers is preferably 1 to 10 mm. For both the principal electrodes 26A and 26B, the small electrodes separated by the spacers from one another are each connected with an AC power source T_{ac}, which is illustrated in FIG. 4 only schematically.

The AC electrolytic cell 20 is provided in its top with the opening 22A, through which the aluminum web W is to be guided to the interior, and again to the exterior, of the AC electrolytic cell body 22. In the vicinity of the opening 22A, the solution feeding nozzle 28A is mounted on the AC electrolytic cell body 22 for the replenishment of the cell body 22 with the aqueous acid solution. In addition, the solution feeding nozzle 28B is mounted separately.

Also in the vicinity of the opening 22A, a group of rollers for guiding the aluminum web W to the interior of the AC electrolytic cell body 22, the upstream-side guide rollers 30A, and a group of rollers for guiding the aluminum web W having been subjected to electrolytic graining treatment in the cell body 22 to the exterior thereof, the downstream-side guide rollers 30B, are positioned above the AC electrolytic cell 20.

The AC electrolytic cell 20 further has the overflow reservoir 32 adjacent to the AC electrolytic cell body 22 on the downstream side of the latter. The overflow reservoir 32 can be stored with the aqueous acid solution as described before, and serves to temporarily reserve the aqueous acid solution overflowing the AC electrolytic cell body 22 and keep the level of the aqueous acid solution in the cell body 22 constant.

The auxiliary electrolytic cell 34 is positioned before (that is to say, on the upstream side of) the AC electrolytic cell body 22. The auxiliary electrolytic cell 34 is shallower than the AC electrolytic cell body 22, and its bottom 34A is formed flat. On the bottom 34A, the auxiliary electrodes 36 are provided as a plurality of cylindrical electrodes. The auxiliary electrolytic cell 34 is stored with the aqueous acid solution as described before.

The auxiliary electrodes 36 are preferably made of a metal of high corrosion resistance including platinum, or ferrite, and may be in a planar shape.

The auxiliary electrodes 36 are connected with the AC power source T_{ac} on the same side as the principal electrode 26A and parallel to the principal electrode 26A. Between the auxiliary electrodes 36 and the AC power source T_{ac}, the thyristor Th4 is so connected that electric current may flow from the above side of the power source T_{ac} to the electrodes 36 when the thyristor is ignited.

The auxiliary electrodes 36 are also connected with the AC power source T_{ac} on the side where the principal electrode 26B is connected, via the thyristor Th5 this time. Similar to the thyristor Th4, the thyristor Th5 is so connected that electric current may flow from the side of the power source T_{ac} where the principal electrode 26B is connected, to the electrodes 36 when the thyristor is ignited.

Since an anode current passes through the auxiliary electrodes 36 whichever thyristor, Th4 or Th5, is ignited, the current value of the anode current passing through the auxiliary electrodes 36 and, consequently, the value of Q_{c}/Qₐ can be controlled by the phase control of the thyristors Th4 and Th5.

The electrolytic graining treatment apparatus 104 operates as follows.

Traveling from the left in FIG. 4, the aluminum web W is initially guided by the upstream-side guide roller 35 to the interior of the auxiliary electrolytic cell 34, and then by the upstream-side guide rollers 30A to the AC electrolytic cell body 22, in which the web W is caused by the feed roller 24 to travel from the left to the right in FIG. 4, before guided by the downstream-side guide rollers 30B to the exterior of the cell body 22.

In the AC electrolytic cell body 22 and the auxiliary electrolytic cell 34, the surface of the aluminum web W that faces the principal electrodes 26A and 26B is grained by the action of the alternating current applied to the principal electrodes 26A and 26B and the anode current applied to the auxiliary electrodes 36 to. have honeycomb pits almost uniformly formed therein.

(4) Recycling of Wastewater from Graining Treatment

It is preferable that the solution having been used for some graining treatment or other (wastewater) be recycled as much as possible.

If an aqueous solution of caustic soda has aluminum dissolved therein in ion form, aluminum and caustic soda can be separated from each other by crystallization. In the case of the aqueous solution of sulfuric acid, nitric acid or hydrochloric acid in which aluminum is dissolved in ion form, sulfuric acid, nitric acid or hydrochloric acid can be recovered by electrodialysis, or with an ion-exchange resin.

If it is the aqueous hydrochloric acid solution which has aluminum dissolved therein in ion form, recovery by evaporation, such as described in JP 2000-282272 A, will also be thinkable.

In the present invention, it is preferable to use the waste electrolyte solution from electrochemical graining treatment for desmutting treatment.

Moreover, the desmutting treatment to be performed before electrochemical graining treatment or anodizing treatment is preferably performed by using the solution of the same kind, more preferably of the same composition, as that used in the subsequent electrochemical graining treatment or anodizing treatment. With such a solution being used, rinsing can be omitted between the desmutting treatment and the subsequent process, resulting in simplified facilities and reduced wastewater.

<Chemical Etching Treatment in Aqueous Alkali Solution (Second Alkali Etching Treatment)>

It is preferable to perform a second alkali etching treatment after the electrochemical graining treatment as above. By doing so, the surface shape of the aluminum plate is made uniform, and a lithographic printing plate which is excellent in press life and printing performance can be obtained.

In the second alkali etching treatment, the aluminum plate is etched by bringing it into contact with an alkali solution. The alkali in the solution to be used, as well as the method and apparatus for bringing the aluminum plate into contact with an alkali solution are each exemplified by those referred to for the first alkali etching treatment.

The alkali in the alkali solution may be the same as in the solution used for the first alkali etching treatment.

The concentration of the alkali solution may be determined in accordance with the etching amount, although it is preferably 0.01 to 80 wt %. The temperature of the alkali solution is preferably 20 to 90° C., and the treatment time is preferably 1 to 60 seconds.

In the case of the second alkali etching treatment, the amount of the aluminum plate dissolved (on the side subjected to electrolytic graining treatment) is preferably 0.01 to 2.0 g/m² and more preferably 0.05 to 1.0 g/m², especially 0.1 to 0.5 g/m².

By increasing the amount of the aluminum plate dissolved in the second alkali etching treatment, the aperture diameter of the small pits can be increased. On the other hand, the ratio of depth to aperture diameter of the small pits and the surface area difference ΔS⁵⁰ can be decreased. <Desmutting Treatment in Aqueous Acid Solution (Second Desmutting Treatment)>

It is preferable to perform a second desmutting treatment after the second alkali etching treatment.

The second desmutting treatment is performed by, for instance, bringing the aluminum plate into contact with an acid solution containing 0.5 to 30 wt % of phosphoric acid, hydrochloric acid, nitric acid or sulfuric acid (also containing 0.01 to 5 wt % of aluminum ions). The method of bringing the aluminum plate into contact with an acid solution may be the same used in the first desmutting treatment.

The acid solution used in the second desmutting treatment is preferably the waste sulfuric acid solution from the anodizing treatment as will be described later. It is also possible to substitute the wastewater with a sulfuric acid solution at a solution temperature of 30 to 90° C. having a sulfuric acid concentration of 100 to 600 g/L and an aluminum ion concentration of 1 to 10 g/L.

In the case of the second desmutting treatment, the solution temperature is preferably 25 to 90° C., and the treatment time is preferably 1 to 180 seconds. The acid solution used in the second desmutting treatment may have aluminum and aluminum-alloying ingredients dissolved therein.

<Anodizing Treatment>

Anodizing treatment is performed on an aluminum plate in order to improve its surface in abrasion resistance. Any electrolyte may be used in the anodizing treatment of an aluminum plate as long as it gives a porous oxide film. In general, sulfuric acid, phosphoric acid, oxalic acid, chromic acid, or a mixture thereof in solution form is used.

The electrolyte concentration is set appropriately for the electrolyte used.

Conditions for anodizing treatment depend upon which electrolyte is used, but an electrolyte concentration of 1 to 80 wt %, a solution temperature of 5 to 70° C., a current density of 1 to 60 A/dm², a voltage of 1 to 100 V, and an electrolysis time of 10 to 300 seconds are generally suitable. When the treatment is performed with sulfuric acid, direct current is typically used, although alternating current is also thinkable. The amount of anodized layer is preferably 1 to 5 g/m². An anodized layer under 1 g/m² in amount will bring about a poor press life, or result in a lithographic printing plate which is liable in its non-image areas to be scratched and, concomitantly, suffer from so-called scumming by scratching, that is to say, staining with ink in scratched spots. In addition, the anodized layer has a tendency to be formed in the marginal region of an aluminum plate in a larger amount. It is preferred that the difference in the amount of anodized layer between the marginal region and the central region of an aluminum plate is not more than 1 g/m².

Anodizing in an aqueous sulfuric acid solution is described in detail in JP 54-128453 A and JP 48-45303 A. The sulfuric acid concentration is preferably 10 to 300 g/L, and the aluminum ion concentration is preferably 1 to 25 g/L. It is more preferable that aluminum sulfate is added to a 50 to 200 g/L aqueous solution of sulfuric acid to make the aluminum ion concentration of the solution 2 to 10 g/L. The solution temperature is preferably 30 to 60° C. With direct current being used, the current density is preferably 1 to 60 A/dm² and more preferably 5 to 40 A/dm². When an aluminum plate is continuously subjected to anodizing treatment, it is particularly preferred in order to get rid of the concentration of electric current causing burnt deposits on the aluminum plate that the treatment is performed initially at a low current density of 5 to 10 A/dm², and then at a higher current density, which is gradually increased up to 30 to 50 A/dm² or more as the treatment progresses. The current density is preferably increased in 5 to 15 steps. In each step, the current density is controlled with the current value from the power supply system dedicated to the relevant step. The power supplying system is preferably of a via-solution type using no conductor roll. An exemplary system is disclosed in JP 2001-11698 A.

Naturally, any of the trace-element ingredients present in an aluminum plate may be dissolved in the aqueous sulfuric acid solution in a minor amount. Since aluminum is dissolved in the aqueous sulfuric acid solution during anodizing treatment, it is necessary for the process control to control the sulfuric acid concentration and the aluminum ion concentration. An aluminum ion concentration set too low is disadvantageous not only economically but also environmentally because the aqueous sulfuric acid solution in which anodizing treatment is to be performed will need to be frequently renewed, leading to an increase in wastewater. On the other hand, an aluminum ion concentration set too high is uneconomic because the electrolytic voltage will rise and the power cost add up accordingly. Preferred combinations of the sulfuric acid concentration, aluminum ion concentration and solution temperature for the anodizing treatment as described above are as follows.

(Combination 1)

Sulfuric acid concentration: 100 to 200 g/L (especially 130 to 180 g/L)

Aluminum ion concentration: 2 to 10 g/L (especially 3 to 7 g/L)

Solution temperature: 30 to 50° C. (especially 33 to 45° C.)

(Combination 2)

Sulfuric acid concentration: 50 to 125 g/L (especially 80 to 120 g/L)

Aluminum ion concentration: 2 to 10 g/L (especially 3 to 7 g/L)

Solution temperature: 40 to 70° C. (especially 50 to 60° C.)

In anodizing treatment, an aluminum plate is supplied with electric power by the direct power supplying system in which a conductor roll is used to supply electric power directly to an aluminum plate, or the indirect, via-solution power supplying system in which electric power is supplied to an aluminum plate via an electrolyte solution.

Usually, the direct power supplying system is employed in an apparatus for anodizing at a relatively low line speed of not more than 30 m/min and a low current density, while the indirect power supplying system is employed in an apparatus for anodizing at a high line speed exceeding 30 m/min and a high current density.

As described on page 289 of “Renzoku Hyomen-Shori Gijutsu (Continuous Surface Treatment Technology)” (published by the Sogo Gijutsu Center on Sep. 30, 1986), the cell layout of an up-and-down type or a straight type can be used under the indirect power supplying system. The direct power supplying system with a conductor roll is disadvantageous for the anodizing treatment at a high speed and a high current density because sparking may occur between the conductor roll and an aluminum web.

Whichever power supplying system, indirect or direct one, is employed, it is preferred in order to reduce the energy loss due to the voltage drop in an aluminum web that anodizing treatment is divided into two processes or more, and a DC power source is connected between the power supplying cell and the oxidizing cell, or between the conductor roll and the oxidizing cell, of the electrolysis apparatus for each individual process.

The conductor roll generally used in the direct power supplying system is made of aluminum. In order to obtain a conductor roll having a prolonged service life, it is preferable that the roll cast in pure aluminum for industrial use is subjected to a high-temperature homogenization treatment so as to make the crystallized Al—Fe products into a single phase of Al₃Fe and thereby improve the corrosion resistance of the roll, as described in JP 61-50138 B.

During anodizing treatment, the Lorentz force acts on an aluminum plate due to the magnetic field produced by a large current passed through a bus bar, which leads to an unwanted meandering of the aluminum plate in web form. It is therefore desirable to adopt such a method as described in JP 57-51290 A.

In addition, the large current passing through the aluminum plate in itself also produces a magnetic field, which causes the Lorentz force to act on the aluminum plate inwardly in the lateral direction, so that the aluminum plate is liable to be broken. For this reason, it is preferred that a plurality of path rolls having a diameter of 100 to 200 mm are arranged in an anodizing treatment tank with a pitch of 100 to 3,000 mm and lapped over one another at an angle of 1 to 15 degrees so as to prevent the aluminum plate from the breakage due to the Lorentz force.

The amount of the anodized layer formed varies on an aluminum plate along the lateral direction, that is to say, a part of an aluminum plate closer to the plate edge has the anodized layer formed thereon in a larger amount and with a larger thickness accordingly. The aluminum plate with such an anodized layer may not be wound up smoothly by a wind-up machine. This problem can be solved by agitating the flow of an electrolyte solution using the method as described in JP 62-30275 B or JP 55-21840 B. If not effective enough by itself, such an agitation is suitably combined with a method in which an aluminum plate in web form is wound up by a wind-up machine which is oscillated with respect to the web in the lateral direction at a frequency of 0.1 to 10 Hz and an amplitude of 5 to 50 mm.

In the anodizing treatment to be performed with sulfuric acid, direct current is generally used, although alternating current is also thinkable. The amount of anodized layer is preferably 1 to 10 g/m². For ordinary materials for a lithographic printing plate, a suitable amount of anodized layer is 1 to 5 g/m². An anodized layer under 1 g/m² in amount will bring about a poor press life, or result in a lithographic printing plate which is liable in its non-image areas to be scratched and, concomitantly, suffer from so-called scumming by scratching, that is to say, staining with ink in scratched spots. In addition, the anodized layer has a tendency to be formed in the marginal region of an aluminum plate in a larger amount. It is preferred that the difference in the amount of anodized layer between the marginal region and the central region of an aluminum plate is not more than 1 g/m². When anodizing treatment is performed continuously, power supply to an aluminum plate is generally carried out by the via-solution power supplying system. The anode for energizing an aluminum plate may be of lead, iridium oxide, platinum or ferrite, although that made primarily of iridium oxide is preferable. Iridium oxide is so used that a base material may be coated with the oxide by heat treatment. A so-called valve metal, such as titanium, tantalum, niobium or zirconium, is used as the base material, with titanium or niobium being preferable. Since the valve metals are of a relatively high electric resistance, it is preferred to use a core of copper and clad the core with a valve metal. In that case, elaborate shapes cannot be imparted to the anode, and it is general that the electrode parts fabricated separately from one another are coated with iridium oxide before they are assembled with bolts and nuts and so forth into the anode of an expected structure.

In the present invention, it is preferred that the acid wastewater from anodizing treatment is used in the desmutting treatments (first and second desmutting treatments) because the solution feeding equipment and concentration adjusting equipment for desmutting treatment solutions can be simplified to reduce the equipment cost.

<Alkali Metal Silicate Treatment>

According to the present invention, the aluminum plate on which the above graining treatments, anodizing treatment, and so forth have been performed as required is subjected to hydrophilizing treatment with an aqueous alkali metal silicate solution (hereafter also referred to as “alkali metal silicate treatment”).

Alkali metal silicate treatment may be performed by following the methods and procedures as described in U.S. Pat. No. 2,714,066 and U.S. Pat. No. 3,181,461, whereupon the Si amount at the surface of the lithographic printing plate support of the present invention should be 3.0 to 15.0 mg/m². The Si amount at the support surface is preferably 3.5 to 10.0 mg/m² and more preferably 4.0 to 8.0 mg/m², especially 4.5 to 6.5 mg/m².

With the Si amount falling within such a range, the resistance to scumming by ink spreading is improved even if an FM screen is used for halftone and the feed of fountain solution is reduced during printing. The press life, water visibility, as well as the resistance to scumming by leaving and scumming by failed deletion are also improved. In this regard, an Si amount of not less than 3.0 mg/m² allows a higher resistance to scumming by ink spreading while an Si amount of not more than 15.0 mg/m² allows a better press life.

The inventor of the present invention has found for the first time that, even if an FM screen is used, not only the press life can be improved but also scumming by ink spreading and by leaving can be prevented and the water visibility made higher by providing the intermediate layer as described later so as to ensure a better press life and, at the same time, increasing the Si amount at the surface of a lithographic printing plate support to a magnitude within the above range so as to improve the water wettability. The present invention was completed under the findings as above.

In the present invention, the Si amount at the surface of a lithographic printing plate support is the amount of the Si atoms deposited to the surface (Si mg/m²) which is measured by a calibration curve method using an X-ray fluorescence spectrometer (XRF). The reference material for the preparation of calibration curve is an aqueous sodium silicate solution containing a known amount of Si atoms, which is uniformly dropped onto a region of 30 mm in diameter of the surface of an aluminum plate and then caused to dry. Conditions for the X-ray fluorescence spectrometry of Si, including the selection of X-ray fluorescence spectrometer, are not particularly limited. Exemplary conditions are as follows.
X-ray fluorescence spectrometer: RIX3000 manufactured by Rigaku Industrial Corporation.
X-ray tube: Rh.
Spectrum to measure: Si—Kα.
Tube voltage: 50 kV.
Tube current: 50 mA.
Slit: COARSE.
Light-dispersing crystal: RX4.
Detector: F—PC.
Region for spectrometry: circular one of 30 mm in diameter.
Peak position (20): 144.75 deg.
Background (20): 140.70 deg. and 146.85 deg.
Integrating time: 80 sec/sample.

Any of alkali metal silicates, including sodium silicate, potassium silicate and lithium silicate, may be used in alkali metal silicate treatment without particular limitation. The silicates may be used singly or in combinations of two or more thereof. The aqueous alkali metal silicate solution may contain an adequate amount of sodium hydroxide, potassium hydroxide or lithium hydroxide.

The aqueous alkali metal silicate solution may also contain an alkaline earth metal salt or a Group 4 (Group IVA) metal salt. Examples of suitable alkaline earth metal salts include nitrates such as calcium nitrate, strontium nitrate, magnesium nitrate and barium nitrate; and also sulfates, hydrochlorides, phosphates, acetates, oxalates, and borates. Exemplary Group 4 (Group IVA) metal salts include titanium tetrachloride, titanium trichloride, titanium potassium fluoride, titanium potassium oxalate, titanium sulfate, titanium tetraiodide, zirconyl chloride, zirconium dioxide, and zirconium tetrachloride. Such alkaline earth metal salts and Group 4 (Group IVA) metal salts may be used singly or in combinations of two or more thereof.

Alkali metal silicate treatment is carried out by bringing the aluminum plate, on which graining treatment, anodizing treatment and so forth have been performed as required, into contact with the aqueous alkali metal silicate solution. The method of bringing the aluminum plate into contact with the aqueous alkali metal silicate solution is not particularly limited, and its examples include a method in which the aluminum plate is caused to pass through a tank filled with the solution, a method in which the aluminum plate is immersed in the solution in a tank, and a method in which the solution is sprayed onto the surface of the aluminum plate.

Conditions for alkali metal silicate treatment are not particularly limited as long as the Si amount falls within the above range, but the solution temperature is preferably 10 to 80° C. and more preferably 15 to 50° C., especially 20 to 40° C. The treatment time is preferably 1 to 100 seconds and more preferably 2 to 20 seconds, especially 3 to 10 seconds.

The pH of the aqueous alkali metal silicate solution used in the alkali metal silicate treatment is 11.5 to 13.0, preferably 11.7 to 12.5, and more preferably 11.8 to 12.3. With the pH of the aqueous alkali metal silicate solution falling within such a range, the resistance to scumming by ink spreading is improved even if an FM screen is used for halftone. To be more specific, a pH of not less than 11.5 allows a higher resistance to scumming by ink spreading even if an FM screen is used for halftone, while a pH of not more than 13.0 allows a higher resistance to scumming by leaving.

It is considered, though not decisively, as the cause for such improvements that the increase in Si amount involves the increase in silanol groups (SiOH groups) on the surface of an aluminum plate, resulting in a higher water wettability.

A pH within the above range may be attained by any suitable method, for instance, by adding the strong alkali as referred to above, including sodium hydroxide, potassium hydroxide and lithium hydroxide, to the solution, or by increasing the alkali metal silicate concentration of the solution. Addition of sodium hydroxide is particularly preferred.

The concentration of the aqueous alkali metal silicate solution is preferably 0.1 to 10 wt % and more preferably 0.5 to 7 wt %, especially 2 to 6 wt %.

<Sealing Treatment>

Apart from the treatments as described above, various sealing treatments may be adopted. The sealing processes generally known as those for an anodized layer, such as steam sealing, boiled water (hot water) sealing, metal salt sealing (chromate/dichromate sealing, nickel acetate sealing, and so forth), fat/oil-impregnation sealing, synthetic resin sealing and low temperature sealing (with potassium ferricyanide, alkaline earth metal salts, and so forth), are usable in sealing treatment, with steam sealing being rather preferred because of the reduction in treatment time, cost, and pollution. JP 4-176690 A describes an example of steam sealing process, in which an anodized layer is brought into contact with pressurized steam, or steam of normal pressure, continuously or discontinuously for some 2 to 180 seconds at a relative humidity of 70% or more and a steam temperature of 95° C. or more. Sealing may also be carried out by immersing the support with an anodized layer in hot water at 80 to 100° C. or an aqueous alkali solution, or spraying the support with the hot water or solution. Instead of or subsequent to such a process, immersing in, or spraying with, a nitrous acid solution may be performed. Preferred examples of the nitrite or the like contained in the nitrous acid solution include LiO₂, NaNO₂, KNO₂, Mg(NO₂)₂, Ca(NO₂)₂, Zn(NO₃)₂, Al(NO₂)₃, Zr(NO₂)₄, Sn(NO₂)₃, Cr(NO₂)₃, Co(NO₂)₂, Mn(NO₂)₂, and Ni(NO₂)₂, with alkali metal nitrites being particularly preferred. These compounds may also be used in combinations of two or more thereof.

Conditions for sealing treatment depend upon the state of a support, and upon which alkali metal is to be used. When sodium nitrite is used, for instance, it is permissible that the concentration is generally 0.001 to 10 wt % and preferably 0.01 to 2 wt %, the bath temperature is generally room temperature to about 100° C. and preferably 60 to 90° C., and the treatment time is generally 15 to 300 seconds and preferably 10 to 180 seconds. The pH of an aqueous nitrous acid solution is preferably so controlled as to be 8.0 to 11.0, more preferably 8.5 to 9.5. Such a control of pH can be carried out suitably by using an alkali buffer solution, for instance. Examples of the alkali buffer solution which is desirable for use include in a non-limitative manner: a mixed aqueous solution of sodium hydrogen carbonate and sodium hydroxide; a mixed aqueous solution of sodium carbonate and sodium hydroxide; a mixed aqueous solution of sodium carbonate and sodium hydrogen carbonate; a mixed aqueous solution of sodium chloride and sodium hydroxide; a mixed aqueous solution of hydrochloric acid and sodium carbonate; and a mixed aqueous solution of sodium tetraborate and sodium hydroxide. Other alkali metal salts than sodium salts, including potassium salts, may also be used in the alkali buffer solution. Following the silicate treatment or sealing treatment as described above, the aqueous acid solution treatment and the formation of a water-receptive undercoat as described in JP 5-278362 A may be performed or the organic layer as described in JP 4-282637 A or JP 7-314937 A may be provided in order to increase the adhesion to an image recording layer.

In the fabrication of the lithographic printing plate support of the present invention, the following treatments may be performed in addition to those as described above.

<Rinsing of Aluminum Plate>

It is general that the aluminum plate subjected to a treatment in an aqueous acid or alkali solution or mechanically grained with an abrasive then undergoes a washing process for removing any remaining solution or abrasive from the plate surface.

Washing is usually performed between any two treatment tanks containing treatment solutions of different kinds or compositions. The time that elapses before the aluminum plate moved out of a treatment tank begins to be washed, or again, before the washed aluminum plate is moved into the next treatment tank is preferably 10 seconds or less, and more preferably 0.1 to 10 seconds. If the time is over 10 seconds, chemical degradation will be promoted at the plate surface, and nonuniform graining may be more liable to take place.

In fact, the time that elapses before the aluminum web moved out of a treatment tank is then rinsed, and at last moved into the next treatment tank is preferably not more than 15 seconds, and more preferably not more than 5 seconds. If the time is more than 15 seconds, chemical degradation may be promoted at the web surface, and uniform graining may hardly be carried out in the next process.

It is preferred that the aluminum plate is washed by either of the following methods, with the rinsing with dry ice powder being more preferred because of the reduction in wastewater.

(1) Washing with Water

In an ordinary method of washing an aluminum plate for lithographic printing plate support, the solution remaining on the plate surface is initially removed with nip rollers, then the surface is washed with the spray of water discharged from a spray tip. It is preferable that water is sprayed downstream in the traveling direction of the aluminum plate at an angle of 45 to 90 degrees. The spray pressure on water is generally 0.5 to 5 kg/cm² just before a spray nozzle, and the liquid temperature is preferably 10 to 80° C. The speed of the traveling aluminum plate is preferably 20 to 200 m/min. It is preferable that water is sprayed onto the aluminum plate in an amount of 0.1 to 10 L/m² for each washing process. In one washing tank, washing water is sprayed from at least two spray lines onto the front side of the aluminum plate and, similarly, from at least two spray lines onto the back side. Each spray line has 5 to 30 spray tips provided thereon at a pitch of 50 to 200 mm. It is preferable that the spray angle of a spray tip is 10 to 150 degrees, and the distance between the aluminum plate and the spray plane of a spray tip is 10 to 250 mm. The cross-sectional shape of the spray of water from a spray tip (that is to say, the spray pattern of a spray tip) may be annular, circular, elliptical, square or rectangular, with a circular or elliptical shape or square or rectangular shape being preferred. The flow distribution (distribution of the amount of sprayed water on the surface of an aluminum plate) may be an annular, homogeneous, or arched distribution. When a plurality of spray tips are aligned on a spray line, an arched distribution is preferred because of readily allowing a uniform flow distribution over the entire width of an aluminum plate. The flow distribution varies with the spray pressure, and the distance between the spray tips and the aluminum plate. The particle diameter of sprayed water varies with the structure of spray tips, the spray pressure and the spray amount, but is preferably 10 to 10,000 μm and more preferably 100 to 1,000 μm. The material for spray nozzles is preferably resistant to the erosion due to the liquid flow at a high speed. Exemplary materials include brass, stainless steel and ceramics, with ceramics being preferred.

The spray nozzle having a spray tip mounted thereon may be positioned at an angle of 45 to 90 degrees with respect to the moving direction of the aluminum plate. In that case, it is preferable that, of the center lines of the spray pattern, the longer one is orthogonal to the moving direction of the aluminum plate.

From an industrial point of view, the washing time, that is to say, the period of time for which the traveling aluminum plate undergoes a rinsing process, is preferably 10 seconds or less, especially 0.5 to 5 seconds.

(2) Washing with Dry Ice Powder

In the method of washing an aluminum plate by subjecting the plate on both its sides to blasting with dry ice powder, a conventional shot-blasting apparatus such as described in JP 10-66905 A may be employed. A plurality of known ejector nozzles such as described in JP 10-28901 A or JP 10-28902 A may be arranged on both sides of an aluminum plate. On each side, the ejector nozzles may be aligned in a row, although it is preferable that they are so obliquely positioned that blast patterns may overlap one another on the surface of the aluminum plate in the lateral direction. The distance between the ejector nozzles and the aluminum plate is preferably 1 to 100 mm and more preferably 10 to 50 mm.

Powdery dry ice may be produced by using such a device as described in JP 7-38140 U. A GN2 gas or air may be used as the gas for blasting. The dry ice powder has a particle size of 1 to 1,000 μm, with a preferred mean particle size being 10 to 100 μm. It is preferable that the feed of LCO₂ (liquefied carbon dioxide gas) per ejector nozzle is 0.1 to 1 kg/min, and the feeding pressure is 1 to 20 MPa. The washing pressure on an aluminum plate is preferably 1 to 20 MPa.

<Material for Path Roll>

Rolls may be selected for use from the known rolls of metal, resin, rubber or nonwoven having the surface subjected to plating or lining treatment, which are adapted for use in a continuous production line of such a product as steel, plated article, electrolytic capacitor and presensitized plate.

The material for a roll and the magnitude of various physical properties of the roll surface are determined in accordance with the treatment solution used and the state of the aluminum surface to which the roll is applied, taking the corrosion resistance, wear resistance, heat resistance, chemical resistance and so forth into account. Out of metal rolls, hard chrome-plated ones are generally used. The material for a rubber roll may be natural rubber, isoprene rubber, styrene-butadiene rubber, butadiene rubber, butyl rubber, chloroprene rubber, chlorosulfonated polyethylene, nitrile rubber, acrylic rubber, epichlorohydrin rubber, urethane rubber, polysulfide rubber, fluorocarbon rubber, or any such rubber containing minor amounts of additives. The international rubber hardness degree (whose use being standardized in JIS K6253) of a rubber roll is preferably 60 to 90.

The lithographic printing plate support of the present invention obtained by the fabrication method as described above in detail can have a surface with uniform asperities, even if an aluminum plate of low purity (aluminum plate containing an alloying ingredient at a higher rate or in an uncontrolled state) is used. With the presensitized plate of the present invention being obtained by forming an image recording layer on the above lithographic printing plate support as will be described later, a lithographic printing plate made from the presensitized plate is excellent in both printing performance and press life.

<Back Coat>

The lithographic printing plate support of the present invention may be provided as required on the back side (that is to say, the side on which no image recording layer is formed) with a coat (hereafter also referred to as “back coat”) composed of an organic polymeric compound so as to prevent the scuffing of an image recording layer when the presensitized plates are stacked on top of each other.

It is preferable that the back coat is composed primarily of at least one resin selected from the group consisting of saturated polyester copolymer resins, phenoxy resins, polyvinyl acetal resins and vinylidene chloride copolymer resins, each having a glass transition point of 20° C. or more.

A saturated polyester copolymer resin comprises a dicarboxylic acid unit and a diol unit. Examples of the dicarboxylic acid unit include an aromatic dicarboxylic acid such as phthalic acid, terephthalic acid, isophthalic acid, tetrabromophthalic acid and tetrachlorophthalic acid; and a saturated aliphatic dicarboxylic acid such as adipic acid, azelaic acid, succinic acid, oxalic acid, suberic acid, sebatic acid, malonic acid and 1,4-cyclohexane dicarboxylic acid.

The back coat may additionally contain, as appropriate, a dye or pigment for coloring, a silane coupling agent for improving the adhesion to the support, a diazo resin comprising a diazonium salt, an organic phosphonic acid, an organic phosphoric acid, a cationic polymer, or a substance conventionally used as a lubricant, such as wax, a higher fatty acid, a higher fatty acid amide, a silicone compound comprising dimethyl siloxane, a modified dimethyl siloxane, and polyethylene powder.

The back coat may have any thickness in principle as long as the image recording layer as described later is substantially prevented from scuffing even without a slip sheet, although a thickness of 0.01 to 8 μm is preferable. If the thickness of the back coat is less than 0.01 μm, the recording layer is hardly prevented from scuffing when the presensitized plates are stacked on top of each other. On the other hand, a thickness of more than 8 μm may deteriorate the printing performance as a result of the change in impression pressure which is caused by the swelling and variation in thickness of the back coat absorbing the chemical solutions used around the lithographic printing plate during printing.

The back coat can be provided on the back side of the support by using various methods. As an example, a solution or emulsion of the back coat components as above in a suitable solvent may be applied to the support and then caused to dry. In another example, a film of back coat material formed in advance may be bonded to the support with an adhesive or heat. It is also possible to bond a film of molten back coat material formed by a melt extruder to the support. In order to secure a preferable thickness, it is most preferred to apply a solution of the back coat components in a suitable solvent to the support and then cause the solution to dry. In this method, such organic solvents as described in JP 62-251739 A may be used singly or in combination.

When the presensitized plate of the invention is fabricated, the back coat on the back side and the intermediate layer and image recording layer on the front side may be provided on the support at different points in time, with either being the first, or simultaneously.

[Intermediate Layer]

Next, description is made about the intermediate layer to be provided on the front side of the support.

According to the present invention, the intermediate layer is not particularly limited as long as it is alkali-soluble, although it is preferable to form the intermediate layer with a polymeric material which includes a constituent bearing an acid group and a constituent bearing an onium group. The presensitized plate of the present invention that has the intermediate layer formed with such a polymeric compound on the lithographic printing plate support as described above is excellent in press life, resistance to scumming by leaving, and resistance to scumming by failed deletion. The polymeric compound is produced by, for instance, polymerizing at least a monomer bearing an acid group together with a monomer bearing an onium group. The following is a detailed description on the polymeric compound.

Preferred acid groups have an acid dissociation exponent (pKₐ) of 7 or less. More preferred are —COOH, —SO₃H, —OSO₃H—, —PO₃H₂, —OPO₃H₂, —CONHSO₂ and —SO₂NHSO₂, especially —COOH.

Preferred onium groups contain an atom of Group 15 (Group VB) or Group 16 (Group VIB) element in the periodic table. More preferred are those containing a nitrogen, phosphorus or sulfur atom, especially those containing a nitrogen atom.

The polymer to be used in the present invention is preferably a polymeric compound which is characterized by having a backbone structure composed of a vinyl polymer such as an acrylic resin, a methacrylic resin and polystyrene, a urethane resin, polyester, or polyamide. It is more preferable that the backbone structure of the polymer is composed of a vinyl polymer such as an acrylic resin, a methacrylic resin and polystyrene. Particularly preferred are the polymeric compounds which are characterized in that the monomer bearing an acid group is a compound expressed by the following general formula (1) or (2) and the monomer bearing an onium group is a compound expressed by the general formula (3), (4) or (5) as shown later.

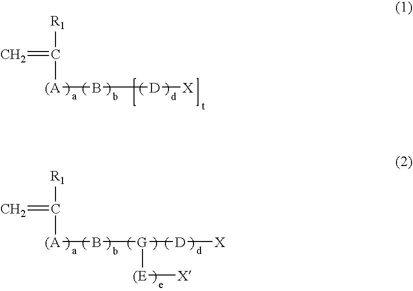

In the formulae: A represents a divalent linking group; B represents an unsubstituted or substituted aromatic group; D and E represent a divalent linking group independently of each other; G represents a trivalent linking group; X and X′ represent, independently of each other, an acid group with a pKa of not more than 7 or an alkali metal salt or ammonium salt thereof; R₁ represents a hydrogen atom, an alkyl group or a halogen atom; a, b, d and e represent 0 or 1 independently of one another; and t is any integer from 1 to 3.

In preferred monomers bearing an acid group: A is —COO— or —CONH—; B is an unsubstituted phenylene group, or a phenylene group substituted with a hydroxy group, a halogen atom or an alkyl group; D and E are independently of each other an alkylene group, or a divalent linking group expressed by the molecular formula CₙH₂ₙO, CₙH₂ₙS or CₙH₂ₙ₊₁N, and G is a trivalent linking group expressed by the molecular formula CₙH₂ₙ₋₁, CₙH₂ₙ₋₁O, CₙH₂ₙ₋₁S or CₙH₂ₙN, with n being any integer from 1 to 12; X and X′ are independently of each other carboxylic acid, sulfonic acid, phosphonic acid, a sulfate monoester, or a phosphate monoester; R₁ is a hydrogen atom or an alkyl group; as well as a, b, d and e are 0 or 1 independently of one another, provided that a and b are not simultaneously 0. More preferred monomers bearing an acid group are the compounds expressed by general formula (1) in which: B is an unsubstituted phenylene group, or a phenylene group substituted with a hydroxy group or an alkyl group of 1 to 3 carbon atoms; D and E are independently of each other an alkylene group of 1 or 2 carbon atoms, or an alkylene group of 1 or 2 carbon atoms that is linked through an oxygen atom; R₁ is a hydrogen atom or an alkyl group; X is a carboxylic acid group; as well as a is 0, and b is 1.

Illustrative examples of the monomer bearing an acid group are as follows. The present invention, however, is in no way limited thereto.

Examples of Monomer with Acid Group

Acrylic acid, methacrylic acid, crotonic acid, isocrotonic acid, itaconic acid, maleic acid, and maleic anhydride.

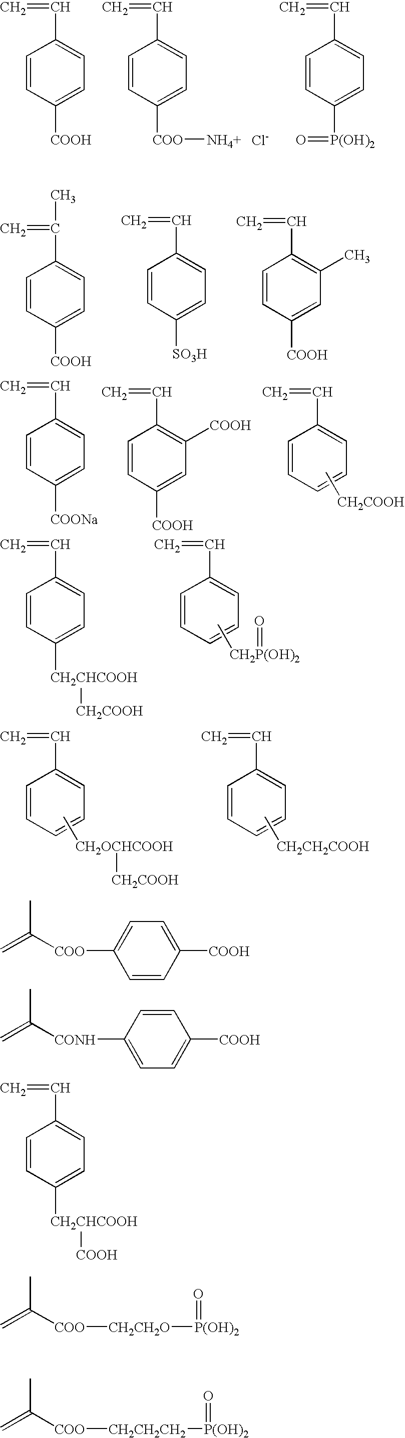

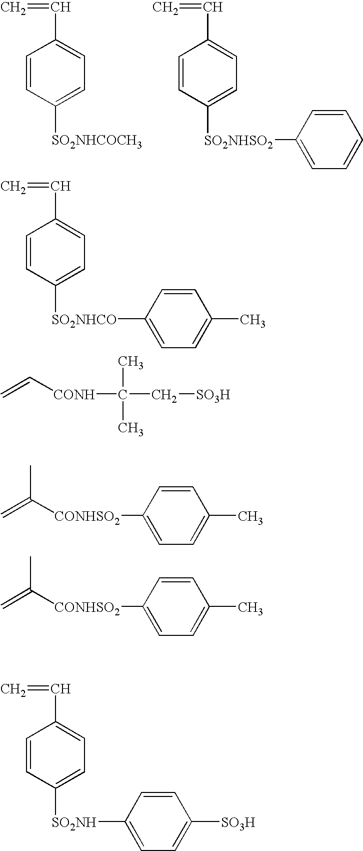

As described before, a particularly preferred polymeric compound includes a monomer bearing an onium group which is expressed by the following general formula (3), (4) or (5).

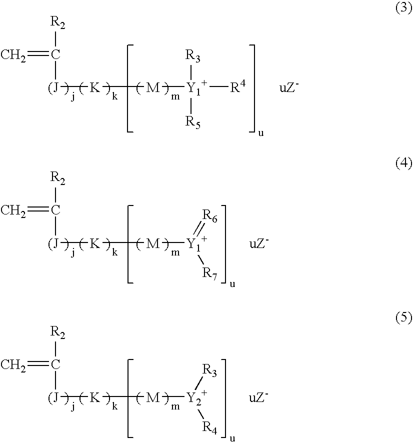

In the formulae: J represents a divalent linking group; K represents an unsubstituted or substituted aromatic group; M independently represents a divalent linking group; Y₁ and Y₂ represent atoms of Group 15 (Group VB) and Group 16 (Group VIB) elements in the periodic table, respectively; Z⁻ represents a counter anion; R₂ represents a hydrogen atom, an alkyl group or a halogen atom; R₃, R₄, R₅ and R₇ represent, independently of one another, a hydrogen atom, or an alkyl group, aromatic group or aralkyl group to which a substituent may be attached, and R₆ represents an unsubstituted or substituted alkylidyne group, whereupon R₃ and R₄, and R₆ and R₇ as well, may be combined together to represent a ring; j, k and m represent 0 or 1 independently of one another; as well as u represents any integer from 1 to 3.

In preferred monomers bearing an onium group: J is —COO— or —CONH—; K is an unsubstituted phenylene group, or a phenylene group substituted with a hydroxy group, a halogen atom or an alkyl group; M is an alkylene group, or a divalent linking group expressed by the molecular formula CₙH₂ₙO, CₙH₂ₙS or CₙH₂₊₁N, with n being any integer from 1 to 12; Y₁ is a nitrogen or phosphorus atom, and Y₂ is a sulfur atom; Z⁻ is a halogen ion, PF₆⁻, BF₄⁻, or R₈SO₃⁻; R₂ is a hydrogen atom or an alkyl group; R₃, R₄, R₅ and R₇ are independently of one another a hydrogen atom, or an alkyl group, aromatic group or aralkyl group of 1 to 10 carbon atoms that a substituent may be attached to, and R₆ is an unsubstituted or substituted alkylidyne group of 1 to 10 carbon atoms, whereupon R₃ and R₄, and R₆ and R₇ as well, may be bonded together to form a ring; j, k and m represent 0 or 1 independently of one another, provided that j and k are not simultaneously 0; as well as R₈ is an alkyl group, aromatic group or aralkyl group of 1 to 10 carbon atoms that a substituent may be attached to.

In more preferred monomers bearing an onium group: K is an unsubstituted phenylene group, or a phenylene group substituted with an alkyl group of 1 to 3 carbon atoms; M is an alkylene group of 1 or 2 carbon atoms, or an alkylene group of 1 or 2 carbon atoms that is linked through an oxygen atom; Z⁻ is a chlorine ion or R₈SO₃⁻; R₂ is a hydrogen atom or a methyl group; j is 0, and k is 1; as well as R₈ is an alkyl group of 1 to 3 carbon atoms.

Illustrative examples of the monomer bearing an onium group are as follows. The present invention, however, is in no way limited thereto.
Examples of Monomer with Onium Group

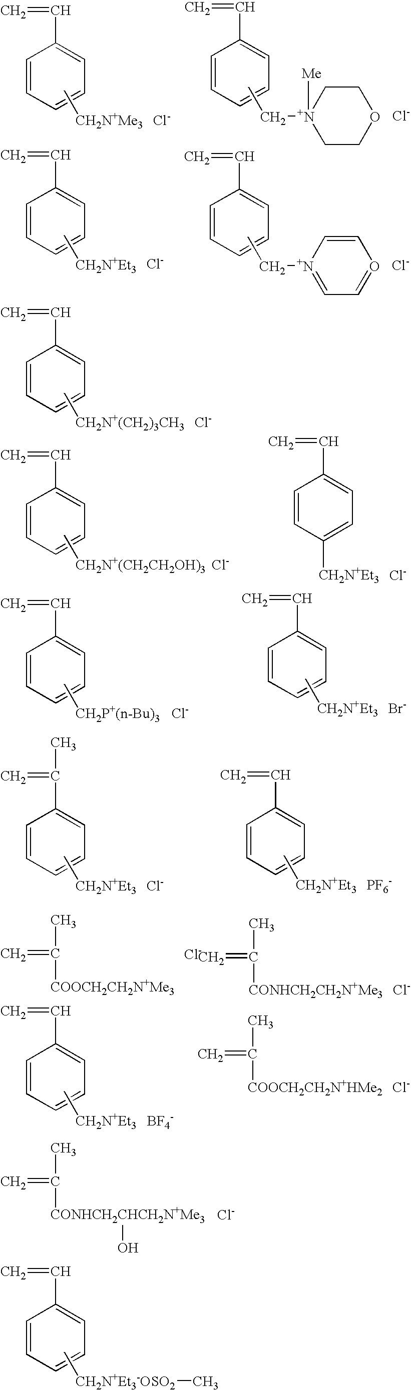

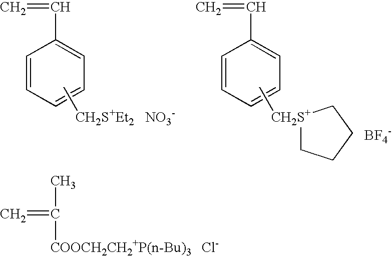

For each of the monomer bearing an acid group and the monomer bearing an onium group, suitable monomers may be used singly or in combinations of two or more thereof. In the present invention, in addition, two or more polymers which are different from one another in constituent monomer, composition or molecular weight may be used in combination.

The polymer to be used in the present invention preferably includes 60 to 80 mol %, more preferably 65 to 75 mol %, of a constituent bearing an acid group and 20 to 40 mol %, more preferably 25 to 35 mol %, of a constituent bearing an onium group.

The polymer which includes a monomer bearing an acid group and a monomer bearing an onium group at ratios within such a range as above will give a presensitized plate further improved in press life and resistance to scumming by failed deletion.

For each of the constituent bearing an acid group and the constituent bearing an onium group, suitable constituents may be used singly or in combinations of two or more thereof. In the present invention, in addition, two or more polymers which are different from one another in constituent monomer, composition or molecular weight may be used in combination.

The above polymer may also include as copolymerizable component or components at least one polymerizable monomer selected from among those set forth in the following (1) to (14):

(1) acrylamides, methacrylamides, acrylic esters, methacrylic esters and hydroxystyrenes having an aromatic hydroxy group, such as N-(4-hydroxyphenyl) acrylamide, N-(4-hydroxyphenyl) methacrylamide, o-, m- or p-hydroxystyrene, o- or m-bromo-p-hydroxystyrene, o- or m-chloro-p-hydroxystyrene, and o-, m- or p-hydroxyphenyl acrylate or methacrylate;

(2) unsaturated carboxylic acids, such as acrylic acid, methacrylic acid, maleic acid, maleic anhydride and half esters thereof, itaconic acid, as well as itaconic anhydride and half ester thereof;

(3) unsaturated sulfonamides, including such acrylamides as N-(o-aminosulfonyl phenyl) acrylamide, N-(m-aminosulfonyl phenyl) acrylamide, N-(p-aminosulfonyl phenyl) acrylamide, N-[1-(3-aminosulfonyl)naphthyl]acrylamide, and N-(2-aminosulfonyl ethyl) acrylamide, such methacrylamides as N-(o-aminosulfonyl phenyl) methacrylamide, N-(m-aminosulfonyl phenyl) methacrylamide, N-(p-aminosulfonyl phenyl) methacrylamide, N-[1-(3-aminosulfonyl)naphthyl]methacrylamide, and N-(2-aminosulfonyl ethyl) methacrylamide, such acrylic esters as o-aminosulfonyl phenyl acrylate, m-aminosulfonyl phenyl acrylate, p-aminosulfonyl phenyl acrylate, and 1-(3-aminosulfonyl phenyl naphthyl) acrylate, as well as such methacrylic esters as o-aminosulfonyl phenyl methacrylate, m-aminosulfonyl phenyl methacrylate, p-aminosulfonyl phenyl methacrylate, and 1-(3-aminosulfonyl phenyl naphthyl) methacrylate;

(4) phenyl sulfonyl acrylamides which may have a substituent, such as tosyl acrylamide, and phenyl sulfonyl methacrylamides which may have a substituent, such as tosyl methacrylamide;

(5) acrylic and methacrylic esters having an aliphatic hydroxy group, such as 2-hydroxyethyl acrylate and 2-hydroxyethyl methacrylate;

(6) (substituted) acrylic esters, such as methyl acrylate, ethyl acrylate, propyl acrylate, butyl acrylate, amyl acrylate, hexyl acrylate, cyclohexyl acrylate, octyl acrylate, phenyl acrylate, benzyl acrylate, 2-chloroethyl acrylate, 4-hydroxybutyl acrylate, glycidyl acrylate, and N-dimethylamino ethyl acrylate;

(7) (substituted) methacrylic esters, such as methyl methacrylate, ethyl methacrylate, propyl methacrylate, butyl methacrylate, amyl methacrylate, hexyl methacrylate, cyclohexyl methacrylate, octyl methacrylate, phenyl methacrylate, benzyl methacrylate, 2-chloroethyl methacrylate, 4-hydroxybutyl methacrylate, glycidyl methacrylate, and N-dimethylamino ethyl methacrylate;

(8) acrylamides and methacrylamides, such as acrylamide, methacrylamide, N-methylol acrylamide, N-methylol methacrylamide, N-ethyl acrylamide, N-ethyl methacrylamide, N-hexyl acrylamide, N-hexyl methacrylamide, N-cyclohexyl acrylamide, N-cyclohexyl methacrylamide, N-hydroxyethyl acrylamide, N-hydroxyethyl methacrylamide, N-phenyl acrylamide, N-phenyl methacrylamide, N-benzyl acrylamide, N-benzyl methacrylamide, N-nitrophenyl acrylamide, N-nitrophenyl methacrylamide, N-ethyl-N-phenyl acrylamide and N-ethyl-N-phenyl methacrylamide;

(9) vinyl ethers, such as ethyl vinyl ether, 2-chloroethyl vinyl ether, hydroxyethyl vinyl ether, propyl vinyl ether, butyl vinyl ether, octyl vinyl ether and phenyl vinyl ether;

(10) vinyl esters, such as vinyl acetate, vinyl chloroacetate, vinyl butyrate and vinyl benzoate;

(11) styrenes, such as styrene, α-methyl styrene, methyl styrene and chloromethyl styrene;

(12) vinyl ketones, such as methyl vinyl ketone, ethyl vinyl ketone, propyl vinyl ketone and phenyl vinyl ketone;

(13) olefins, such as ethylene, propylene, isobutylene, butadiene and isoprene; as well as

(14) N-vinyl pyrrolidone, N-vinyl carbazole, 4-vinyl pyridine, acrylonitrile, methacrylonitrile, and so forth.

Typical examples of the polymer to be used in the present invention are as follows. The proportion of the monomers constituting a polymer is shown on a mole percentage basis.

TYPICAL EXAMPLES OF POLYMERS

| | | NUMBER-AVERAGE |
|---|---|---|
| STRUCTURE | | MOLECULAR WEIGHT (Mn) |
| No.1 | 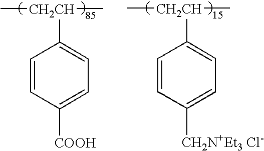 | 2,100 |
| No.2 | 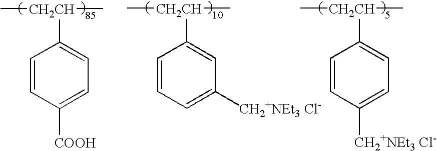 | 4,800 |
| No.3 | 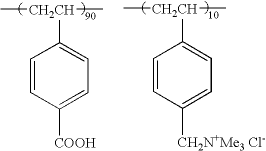 | 3,200 |
| No.4 | 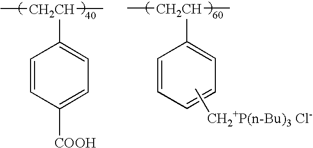 | 2,300 |
| No.5 | 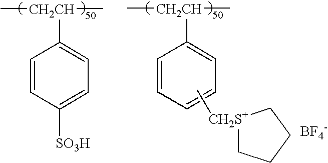 | 1,400 |
| No.6 | 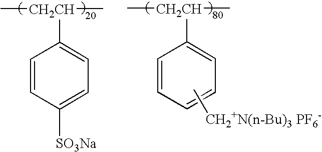 | 4,500 |
| No.7 | 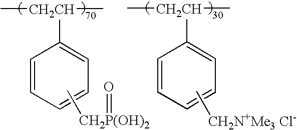 | 5,000 |
| No.8 | 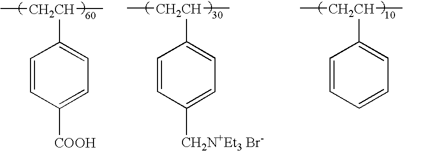 | 1,000 |
| No.9 | 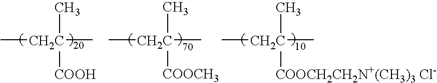 | 1,300 |
| No.10 | 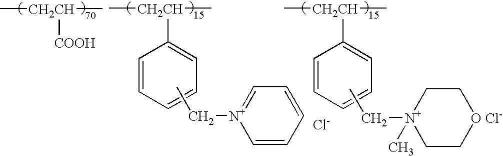 | 2,900 |
| No.11 | 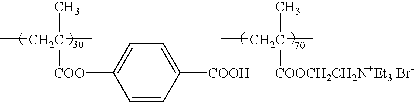 | 800 |
| No.12 | 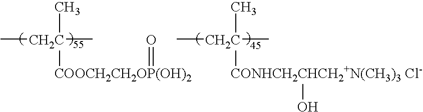 | 300 |
| No.13 | 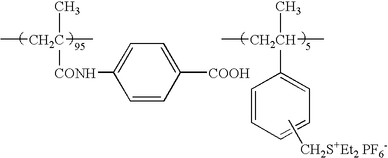 | 1,900 |
| No.14 | 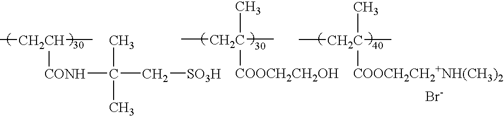 | 4,100 |
| No.15 | 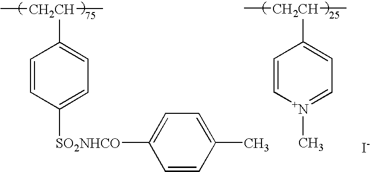 | 3,500 |
| No.16 | 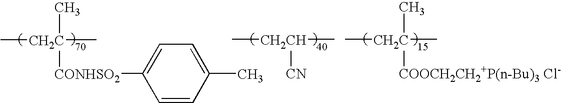 | 3,000 |
| No.17 | 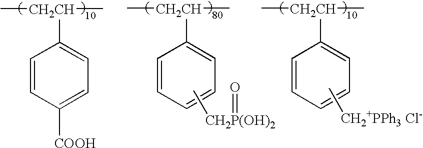 | 3,300 |
| No.18 | 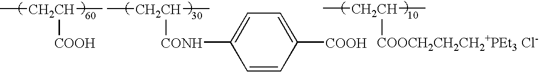 | 600 |
| No.19 | 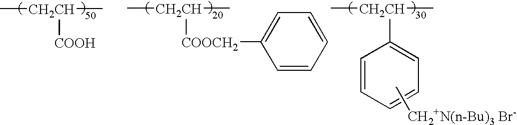 | 5,000 |
| No.20 | 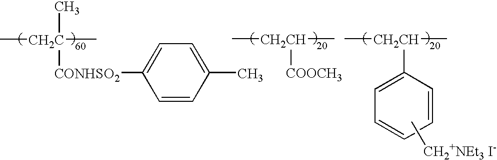 | 2,400 |
| No.21 | 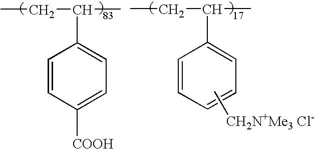 | 32 THOUSAND |
| No.22 | 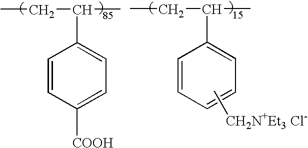 | 28 THOUSAND |
| No.23 | 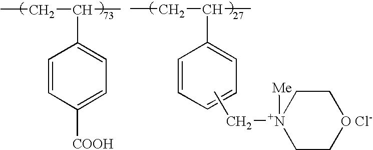 | 26 THOUSAND |
| No.24 | 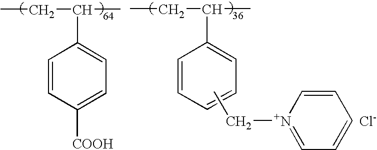 | 41 THOUSAND |
| No.25 | 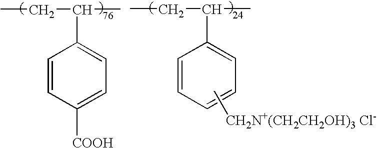 | 11 THOUSAND |
| No.26 | 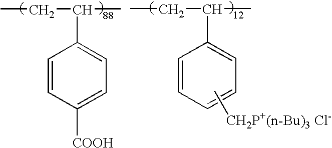 | 17 THOUSAND |
| No.27 | 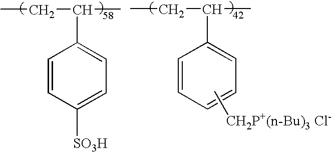 | 36 THOUSAND |
| No.28 | 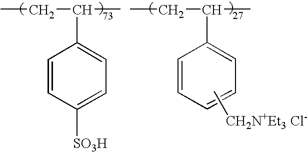 | 22 THOUSAND |
| No.29 | 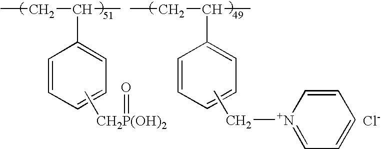 | 44 THOUSAND |
| No.30 | 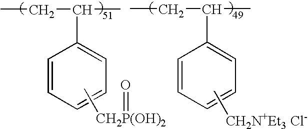 | 19 THOUSAND |
| No.31 | 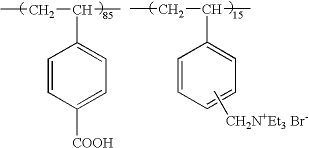 | 28 THOUSAND |
| No.32 | 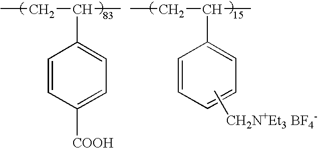 | 28 THOUSAND |
| No.33 | 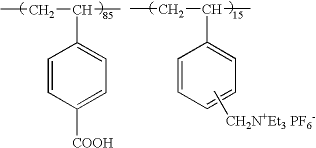 | 28 THOUSAND |
| No.34 | 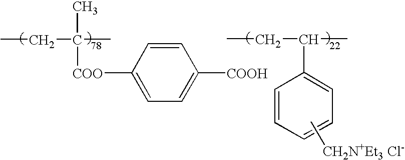 | 34 THOUSAND |
| No.35 | 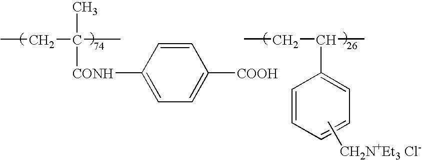 | 42 THOUSAND |
| No.36 | 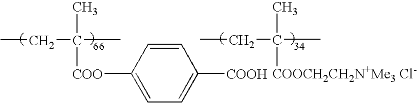 | 13 THOUSAND |
| No.37 | 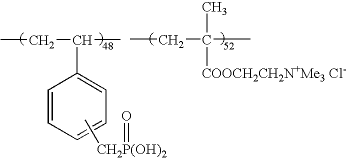 | 15 THOUSAND |
| No.38 | 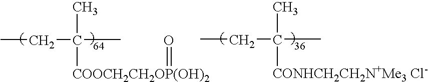 | 46 THOUSAND |
| No.39 | 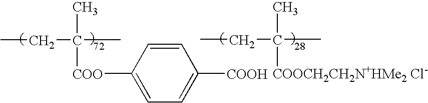 | 34 THOUSAND |
| No.40 | 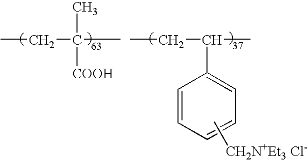 | 63 THOUSAND |
| No.41 | 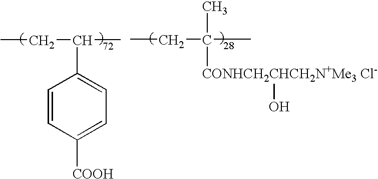 | 25 THOUSAND |
| No.42 | 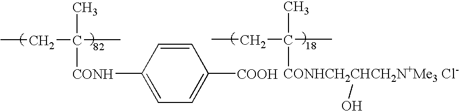 | 25 THOUSAND |
| No.43 | 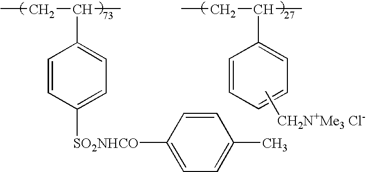 | 33 THOUSAND |
| No.44 | 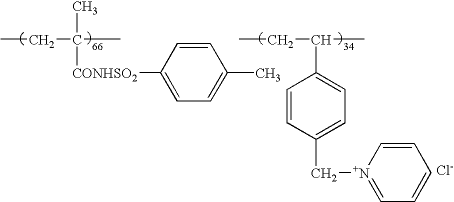 | 41 THOUSAND |
| No.45 | 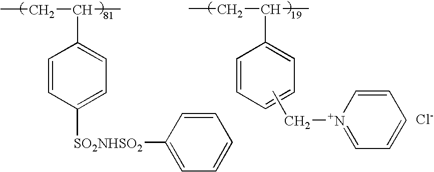 | 14 THOUSAND |
| No.46 | 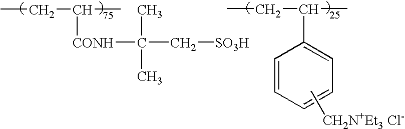 | 22 THOUSAND |
| No.47 | 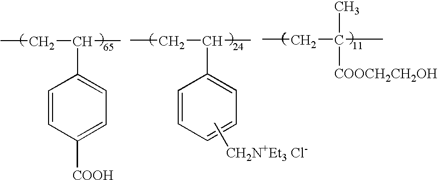 | 23 THOUSAND |
| No.48 | 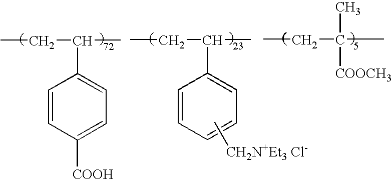 | 47 THOUSAND |

The polymer to be used in the present invention may generally be produced using radical chain polymerization processes (see Textbook of Polymer Science, 3rd ed., F. W. Billmeyer, Wiley-Interscience Publication, 1984).

The molecular weight of the polymer to be used in the present invention does not need to be limited within a narrower range, although the weight-average molecular weight (M_{w}) measured by using the light scattering method is preferably 500 to 2,000,000 and more preferably 1,000 to 600,000. The number-average molecular weight (Mₙ) which is calculated from the integrated intensity of end groups and side-chain functional groups found in the NMR measurement is preferably 300 to 500,000 and more preferably 500 to 100,000. With the molecular weight being under such a range, the polymer may adhere poorly to the support, leading to a reduction in press life. On the other hand, a molecular weight over such a range may result in too firm an adhesion of the polymer to the support and allow only an inadequate removal of the photosensitive layer remaining in the non-image areas. The amount of the unreacted monomers in the polymer does not need to be limited within a narrower range, but is preferably 20 wt % or less and more preferably 10 wt % or less.

The polymer having a molecular weight within such a range as above may be obtained by using a polymerization initiator and a chain transfer agent together at controlled addition levels during the copolymerization of appropriate monomers. The chain transfer agent refers to the substance which transfers the active site of polymerization reaction by the chain transfer reaction, and its tendency to chain transfer reaction is represented by the chain transfer constant Cₛ. The chain transfer constant Cₛ (×10⁴; 60° C.) of the chain transfer agent to be used in the present invention is preferably not less than 0.01 and more preferably not less than 0.1, especially not less than 1. As for the polymerization initiator, any of the peroxides, azo compounds and redox initiators generally used in radical polymerization as the polymerization initiator may be employed as such. Among them, azo compounds are preferable.

Illustrative examples of the chain transfer agent include in a non-limitative manner: halogen compounds such as carbon tetrachloride and carbon tetrabromide; alcohols such as isopropyl alcohol and isobutyl alcohol; olefins such as 2-methyl-1-butene and 2,4-diphenyl-4-methyl-1-pentene; and sulfur-containing compounds such as ethanethiol, butanethiol, dodecanethiol, mercaptoethanol, mercaptopropanol, methyl mercaptopropionate, ethyl mercaptopropionate, mercaptopropionic acid, thioglycolic acid, ethyl disulfide, sec-butyl disulfide, 2-hydroxyethyl disulfide, thiosalicylic acid, thiophenol, thiocresol, benzylmercaptan and phenethylmercaptan.

Preferred chain transfer agents are ethanethiol, butanethiol, dodecanethiol, mercaptoethanol, mercaptopropanol, methyl mercaptopropionate, ethyl mercaptopropionate, mercaptopropionic acid, thioglycolic acid, ethyl disulfide, sec-butyl disulfide, 2-hydroxyethyl disulfide, thiosalicylic acid, thiophenol, thiocresol, benzylmercaptan and phenethylmercaptan, and more preferred ones are ethanethiol, butanethiol, dodecanethiol, mercaptoethanol, mercaptopropanol, methyl mercaptopropionate, ethyl mercaptopropionate, mercaptopropionic acid, thioglycolic acid, ethyl disulfide, sec-butyl disulfide and 2-hydroxyethyl disulfide.

<Formation of Intermediate Layer>

The intermediate layer used in the present invention can be provided by various methods of coating the lithographic printing plate support as described before with a coating solution prepared by the dissolution of the intermediate layer components as above (coating solution for intermediate layer formation). No limitations are put on the method of coating the support with a coating solution for intermediate layer formation, and the intermediate layer is typically provided by: (1) applying a solution prepared by dissolving the polymer defined in the present invention in an organic solvent such as methanol, ethanol, methyl ethyl ketone or a mixture thereof, or a mixture of such an organic solvent and water, onto the support, and then causing the solution to dry; or (2) immersing the support in a solution prepared by dissolving the polymer defined in the present invention in an organic solvent such as methanol, ethanol, methyl ethyl ketone or a mixture thereof, or a mixture of such an organic solvent and water, then cleaning the support with water, air or the like, and drying the support.

In the coating method (1), the solution containing the above compounds in a total concentration of 0.005 to 10 wt % may be applied in various ways. In this regard, any coating means may be used including means for bar coater coating, spin coating, spray coating, and curtain coating. In the coating method (2), the concentration of the solution is 0.005 to 20 wt %, preferably 0.01 to 10 wt %, the immersing temperature is 0 to 70° C., preferably 5 to 60° C., and the immersing time is 0.1 seconds to 5 minutes, preferably 0.5 to 120 seconds.

The coating solution for intermediate layer formation as above may be used after adjusting its pH to 0 to 12, preferably 0 to 6, with a basic substance such as ammonia, triethylamine and potassium hydroxide; an inorganic acid such as hydrochloric acid, phosphoric acid, sulfuric acid and nitric acid; an organic acid substance such as an organic sulfonic acid including nitrobenzenesulfonic acid and naphthalenesulfonic acid, an organic phosphonic acid including phenylphosphonic acid, as well as an organic carboxylic acid including benzoic acid, coumaric acid and malic acid; or an organic chloride such as naphthalenesulfonyl chloride and benzenesulfonyl chloride. For the purpose of improving the tone reproducibility of a lithographic printing plate, an ultraviolet-, visible light- or infrared-absorbing substance may be added to the coating solution for intermediate layer formation.

In the present invention, it is suitable that the coating amount of the intermediate layer after drying is 1 to 100 mg/m² in total, with an amount of 2 to 70 mg/M² being preferable.

Owing to the intermediate layer provided as described above, the presensitized plate of the present invention allows the press life, resistance to scumming by ink spreading, resistance to scumming by leaving, water visibility, and resistance to scumming by failed deletion to be excellent, even if an FM screen is used for halftone.

While effects of the intermediate layer used in the present invention are not well-defined, removal of the intermediate layer by using a deletion fluid is considered to be made easier by the reduction in the interaction between the intermediate layer and the aluminum plate during the removal.

The image recording layer containing an alkali-soluble polymeric compound and a photothermal conversion substance (image recording layer of a thermal positive type) as described later may not be removed from the non-image areas completely because the reaction during exposure generally does not progress in the layer to the vicinity of the support surface due to the diffusion of heat into the support. In the present invention, the polymer used for the intermediate layer is readily removable with a developer, and this feature is considered to effectively prevent the scumming by ink spreading which may occur when an image recording layer of a thermal positive type is provided.

[Image Recording Layer]

The presensitized plate of the present invention is obtainable by providing an image recording layer on the intermediate layer which is provided on a lithographic printing plate support as described above. It should be noted that the presensitized plate of the invention, as having the intermediate layer as described above and the image recording layer as described below provided on the lithographic printing plate support as described before in this order, may have an additional layer (the back coat as described before or the over coat as described later, for instance) as appropriate.

A photosensitive-composition is used for the image recording layer. Non-limitative examples of the photosensitive composition suitably used in the present invention include thermal positive-type photosensitive compositions containing an alkali-soluble polymeric compound and a photothermal conversion substance (such compositions and the image recording layers formed with them are hereafter referred to as “thermal positive-type” compositions and image recording layers), thermal negative-type photosensitive compositions containing a curable compound and a photothermal conversion substance (such compositions and the image recording layers formed with them are hereafter referred to as “thermal negative-type” compositions and image recording layers), photopolymerizable photosensitive compositions (such compositions and the image recording layers formed with them are hereafter referred to as “photopolymer-type” compositions and image recording layers), negative-type photosensitive compositions containing a diazo resin or a photo-crosslinkable resin (such compositions and the image recording layers formed with them are hereafter referred to as “conventional negative-type” compositions and image recording layers), positive-type photosensitive compositions containing a quinonediazide compound (such compositions and the image recording layers formed with them are hereafter referred to as “conventional positive-type” compositions and image recording layers), and photosensitive compositions which do not require a special development process (such compositions and the image recording layers formed with them are hereafter referred to as “non-treatment-type” compositions and image recording layers).

Image recording layers of a thermal positive type, thermal negative type, or the like are suitable for the computer-to-plate (CTP) technology in which a lithographic printing plate is directly made through no lith film by subjecting a presensitized plate to the exposure by scanning with a high-convergence radiation such as a laser beam which is caused to carry digitized image information. It is preferable that the image recording layer is image-formable by the exposure with an infrared laser beam and, accordingly, applicable to a CTP use.

The following is a description on the suitable photosensitive compositions as above.

<Thermal Positive-Type Compositions>

<Photosensitive Layer>

Thermal positive-type photosensitive compositions contain an alkali-soluble polymeric compound and a photothermal conversion substance. In a thermal positive-type image recording layer, the photothermal conversion substance converts light energy such as from an infrared laser into heat, which efficiently eliminates interactions that lower the alkali solubility of the alkali-soluble polymeric compound.

The alkali-soluble polymeric compound may be, for example, a resin having an acidic group on the molecule, or a mixture of two or more such resins. Resins having such an acidic group as a phenolic hydroxy group, a sulfonamide group (—SO₂NH—R, wherein R is a hydrocarbon group) or an active imino group (—SO₂NHCOR, —SO₂NHSO₂R or —CONHSO₂R, wherein R is as defined above) are preferable on account of their solubility in alkaline developers.

Among others, resins having phenolic hydroxy groups are desirable because of an excellent image formability under the exposure with light from an infrared laser, for example. Preferred examples of such resins include novolak resins such as phenol-formaldehyde resins, m-cresol-formaldehyde resins, p-cresol-formaldehyde resins, cresol-formaldehyde resins in which the cresol is a mixture of m-cresol and p-cresol, and phenol/cresol mixture-formaldehyde resins (phenol-cresol-formaldehyde co-condensation resins) in which the cresol may be m-cresol, p-cresol, or a mixture of m-cresol and p-cresol.

Additional preferred examples include the polymeric compounds described in JP 2001-305722 A (especially paragraphs [0023] to [0042]), the polymeric compounds having repeating units of general formula (1) described in JP 2001-215693 A, and the polymeric compounds described in JP 2002-311570 A (especially paragraph [0107]).

To provide a good recording sensitivity, the photothermal conversion substance is preferably a pigment or dye which absorbs the light with a wavelength of 700 to 1200 nm in the infrared region. Illustrative examples of suitable dyes include azo dyes, metal complex azo dyes, pyrazolone azo dyes, naphthoquinone dyes, anthraquinone dyes, phthalocyanine dyes, carbonium dyes, quinoneimine dyes, methine dyes, cyanine dyes, squarylium dyes, pyrylium salts, and metal-thiolate complexes (e.g., nickel-thiolate complexes) . Of these, cyanine dyes are preferred. The cyanine dyes of general formula (I) described in JP 2001-305722 A are especially preferred.

A dissolution inhibitor may be included in thermal positive-type photosensitive compositions. Preferred examples of dissolution inhibitors include those described in paragraphs [0053] to [0055] of JP 2001-305722 A.

The thermal positive-type photosensitive compositions preferably also include, as additives, sensitivity regulators, print-out agents for obtaining a visible image immediately after the heating resulting from exposure, compounds such as dyes as image colorants, and surfactants for enhancing coatability and treatment stability. Compounds such as described in paragraphs [0056] to [0060] of JP 2001-305722 A are preferred additives.

Use of the photosensitive compositions described in detail in JP 2001-305722 A is desirable because of the above preferred components and additional advantages.

The thermal positive-type image recording layer is not limited to a single layer, but may have a two-layer construction.

Preferred examples of image recording layers with a two-layer construction (also referred to as “multilayer-type image recording layers”) include those comprising a bottom layer (“layer A”) of excellent press life and solvent resistance which is provided on the side close to the support and a layer (“layer B”) having an excellent positive-image formability which is provided on layer A. This type of image recording layer has a high sensitivity and can provide a broad development latitude. Layer B generally contains a photothermal conversion substance. Preferred examples of the photothermal conversion substance include the dyes mentioned above.

Preferred examples of resins that may be used in layer A include polymers that contain as a copolymerizable component a monomer having a sulfonamide group, an active imino group or a phenolic hydroxy group; such polymers have an excellent press life and solvent resistance. Preferred examples of resins that may be used in layer B include phenolic hydroxy group-bearing resins which are soluble in aqueous alkali solutions.

In addition to the above resins, various additives may be included, if necessary, in the compositions used to form layers A and B. For example, suitable use can be made of the additives described in paragraphs [0062] to [0085] of JP 2002-3233769 A. The additives described in paragraphs [0053] to [0060] of JP 2001-305722 A as above are also suitable for use.

The components and proportions thereof in each of layers A and B are preferably selected as described in JP 11-218914 A.

<Others>

The methods described in detail in JP 2001-305722 A may be used to form a thermal positive-type image recording layer and to make a printing plate having such a layer.

<Thermal Negative-Type Compositions>

Thermal negative-type photosensitive compositions contain a curable compound and a photothermal conversion substance. A thermal negative-type image recording layer is a negative-type photosensitive layer in which areas irradiated with light such as from an infrared laser cure to form image areas.

<Polymerizable Layer>

An example of a preferred thermal negative-type image recording layer is a polymerizable image recording layer (hereafter abbreviated as “polymerizable layer”) . The polymerizable layer contains a photothermal conversion substance, a radical generator, a radical-polymerizable compound which is a curable compound, and a binder polymer. In the polymerizable layer, the photothermal conversion substance converts absorbed infrared light into heat, and the heat decomposes the radical generator, with radicals being thus generated. The radicals then trigger the chain polymerization and curing of the radical-polymerizable compound.

Illustrative examples of the photothermal conversion substance include photothermal conversion substances that may be used in the above-described thermal positive-type compositions. Specific examples of cyanine dyes, which are especially preferred, include those described in paragraphs [0017] to [0019] of JP 2001-133969 A.

Preferred radical generators include onium salts. The onium salts described in paragraphs [0030] to [0033] of JP 2001-133969 A are especially preferred.

Exemplary radical-polymerizable compounds include compounds having one, and preferably two or more, terminal ethylenically unsaturated bonds.

Preferred binder polymers include linear organic polymers. Linear organic polymers which are soluble or swellable in water or a weak alkali solution in water are preferred. Of these, (meth)acrylic resins having unsaturated groups (e.g., allyl, acryloyl) or benzyl groups and carboxy groups in side chains are especially preferred because they provide an excellent balance of film strength, sensitivity and developability.

Radical-polymerizable compounds and binder polymers that may be used include those described specifically in paragraphs [0036] to [0060] of JP 2001-133969 A.

Thermal negative-type photosensitive compositions preferably contain the additives (e.g., surfactants for enhancing coatability) described in paragraphs [0061] to [0068] of JP 2001-133969 A.

The methods described in detail in JP 2001-133969 A may be used to form a polymerizable layer and to make a printing plate having such a layer.

<Acid-Crosslinkable Layer>

Another preferred thermal negative-type image recording layer is an acid-crosslinkable image recording layer (hereafter abbreviated as “acid-crosslinkable layer”). An acid-crosslinkable layer contains a photothermal conversion substance, a thermal acid generator, a compound (crosslinker) which is curable and which crosslinks under the influence of an acid, and an alkali-soluble polymeric compound which is capable of reacting with the crosslinker in the presence of an acid. In an acid-crosslinkable layer, the photothermal conversion substance converts absorbed infrared light into heat. The heat decomposes the thermal acid generator, thereby generating the acid which causes the crosslinker and the alkali-soluble polymeric compound to react and cure.

The photothermal conversion substance is exemplified by the same substances as can be used in the polymerizable layer.

Exemplary thermal acid generators include photopolymerization initiators, dye photochromogenic substances, and heat-decomposable compounds such as acid generators which are used in microresists and the like.

Exemplary crosslinkers include hydroxymethyl- or alkoxymethyl-substituted aromatic compounds, compounds having N-hydroxymethyl, N-alkoxymethyl or N-acyloxymethyl groups, and epoxy compounds.

Exemplary alkali-soluble polymeric compounds include novolak resins, and polymers having hydroxyaryl groups in side chains.

<Photopolymer-Type Compositions>

Photopolymerizable photosensitive compositions contain an addition-polymerizable compound, a photopolymerization initiator and a polymer binder.

Preferred addition-polymerizable compounds include compounds containing an ethylenically unsaturated bond which are addition-polymerizable. Ethylenically unsaturated bond-containing compounds are compounds which have a terminal ethylenically.unsaturated bond. Such compounds may have the chemical form of a monomer, a prepolymer, or a mixture thereof. The compounds in monomer form are exemplified by esters of unsaturated carboxylic acids (e.g., acrylic acid, methacrylic acid, itaconic acid, maleic acid) and aliphatic polyols, and amides of unsaturated carboxylic acids and aliphatic polyamines.

Preferred addition-polymerizable compounds also include urethane-type addition-polymerizable compounds.

The photopolymerization initiator may be any of various photopolymerization initiators or a combined system of two or more photopolymerization initiators (photoinitiation system) which is suitably selected according to the wavelength of the light source to be used. Preferred examples include the initiation systems described in paragraphs [0021] to [0023] of JP 2001-22079 A.

The polymer binder should be an organic high polymer which not only functions as a film-forming agent for the photopolymerizable photosensitive composition but is also soluble or swellable in an aqueous alkali solution because the image recording layer needs to be dissolved in an alkaline developer. Preferred examples of such an organic high polymer include those described in paragraphs [0036] to [0063] of JP 2001-22079 A.

It is preferable for the photopolymer-type photosensitive composition to include the additives (e.g., surfactants for improving coatability, colorants, plasticizers, thermal polymerization inhibitors) described in paragraphs [0079] to [0088] of JP 2001-22079 A.

To prevent polymerization from being inhibited by oxygen, it is preferable to provide an oxygen-blocking protective layer on top of the photopolymer-type image recording layer. The polymer present in the oxygen-blocking protective layer is exemplified by polyvinyl alcohols and copolymers thereof.

<Conventional Negative-Type Compositions>

Conventional negative-type photosensitive compositions contain a diazo resin or a photo-crosslinkable resin. Among others, photosensitive compositions which contain a diazo resin and an alkali-soluble or -swellable polymeric compound (binder) are preferred.

The diazo resin is exemplified by condensation products of an aromatic diazonium salt with an active carbonyl group-bearing compound such as formaldehyde; and organic solvent-soluble diazo resin inorganic salts which are the reaction products of a hexafluorophosphate or tetrafluoroborate with the condensation product of a p-diazophenylamine with formaldehyde. The high-molecular-weight diazo compounds described in JP 59-78340 A, in which the content of hexamer and larger polymers is at least 20 mol %, are especially preferred.

Exemplary binders include copolymers containing acrylic acid, methacrylic acid, crotonic acid or maleic acid as an essential component. Specific examples include the multi-component copolymers of such monomers as 2-hydroxyethyl (meth)acrylate, (meth)acrylonitrile and (meth)acrylic acid described in JP 50-118802 A, and the multi-component copolymers of alkyl acrylates, (meth)acrylonitrile and unsaturated carboxylic acids described in JP 56-4144 A.

Conventional negative-type photosensitive compositions preferably contain as additives the print-out agents, dyes, plasticizers for imparting flexibility and wear resistance to the formed layer, development promoters and other compounds, and surfactants for enhancing coatability described in paragraphs [0014] to [0015] of JP 7-281425 A.

<Conventional Positive-Type Compositions>

Conventional positive-type photosensitive compositions contain a quinonediazide compound. Photosensitive compositions containing an o-quinonediazide compound and an alkali-soluble polymeric compound are especially preferred.

Illustrative examples of the o-quinonediazide compound include esters of 1,2-naphthoquinone-2-diazido-5-sulfonyl chloride and phenol-formaldehyde resins or cresol-formaldehyde resins, and the esters of 1,2-naphthoquinone-2-diazido-5-sulfonyl chloride and pyrogallol-acetone resins described in U.S. Pat. No. 3,635,709.

Illustrative examples of the alkali-soluble polymeric compound include phenol-formaldehyde resins, cresol-formaldehyde resins, phenol-cresol-formaldehyde co-condensation resins, polyhydroxystyrene, N-(4-hydroxyphenyl)methacrylamide copolymers, the carboxy group-bearing polymers described in JP 7-36184 A, such phenolic hydroxy group-bearing acrylic resins as described in JP 51-34711 A, the sulfonamide group-bearing acrylic resins described in JP 2-866 A, and urethane resins.

Conventional positive-type photosensitive compositions preferably contain as additives the compounds such as sensitivity regulators, print-out agents and dyes described in paragraphs [0024] to [0027] of JP 7-92660 A, and surfactants for enhancing coatability such as are described in paragraph [0031] of JP 7-92660 A.

<Non-Treatment-Type Compositions>

Illustrative examples of non-treatment-type photosensitive compositions include those based on a particulate thermoplastic polymer, those in microcapsule form, and those containing a sulfonic acid-generating polymer. All of these are heat-sensitive compositions containing a photothermal conversion substance. The photothermal conversion substance is preferably a dye of the same type as those which can be used in the above-described thermal positive-type compositions.

Particulate thermoplastic polymer-based photosensitive compositions are composed of fine particles of a hydrophobic and heat-meltable polymer which are dispersed in a hydrophilic polymer matrix. In the particulate thermoplastic polymer-based image recording layer, the fine particles of hydrophobic polymer melt under the influence of heat generated by light exposure to fuse together, forming hydrophobic areas which serve as the image areas.

The particulate polymer is preferably one in which the fine particles melt and fuse together under the influence of heat. A particulate polymer in which the individual particles have a hydrophilic surface, enabling them to disperse in a hydrophilic component such as fountain solution, is especially preferred. Preferred examples include the particulate thermoplastic polymers described in Research Disclosure No. 33303 (January 1992), JP 9-123387 A, JP 9-131850 A, JP 9-171249 A, JP 9-171250 A and EP 931,647 A. Of these, polystyrene and polymethyl methacrylate are preferred. Illustrative examples of particulate polymers having a hydrophilic surface include those in which the polymer itself is hydrophilic, and those in which the surfaces of the polymer particles have been rendered hydrophilic by causing a hydrophilic compound such as polyvinyl alcohol or polyethylene glycol to adsorb thereon.

The particulate polymer preferably has reactive functional groups.

Preferred examples of photosensitive compositions in microcapsule form include those described in JP 2000-118160 A, and such compositions as described in JP 2001-277740 A in which a compound having thermally reactive functional groups is enclosed within microcapsules.

Illustrative examples of sulfonic acid-generating polymers that may be used in photosensitive compositions containing a sulfonic acid-generating polymer include the polymers described in JP 10-282672 A that have sulfonate ester groups, disulfone groups, or sec- or tert-sulfonamide groups in side chains.

Including a hydrophilic resin in a non-treatment-type photosensitive composition not only provides a good on-press developability but also enhances the film strength of the photosensitive layer itself. Preferred hydrophilic resins include resins having hydrophilic groups such as hydroxy, carboxy, hydroxyethyl, hydroxypropyl, amino, aminoethyl, aminopropyl or carboxymethyl groups; and hydrophilic binder resins of a sol-gel conversion type.

A non-treatment-type image recording layer can be developed on the printing press, and thus does not require a special development process. The methods described in detail in JP 2002-178655 A may be used as the method of forming a non-treatment-type image recording layer and the associated platemaking and printing methods.

<Overcoat>

In the case of the presensitized plate of a non-treatment type, a water-soluble overcoat may be provided on the heat-sensitive image recording layer so as to prevent the layer surface from being contaminated by hydrophobic substances. The water-soluble overcoat used in the present invention is preferably easy to remove during printing, and contains a resin selected from among the organic polymeric compounds which are water-soluble.

The water-soluble, organic polymeric compounds should be such that the coat provided by applying the material containing any such compound and then causing the material to dry retains its filming characteristics. Illustrative examples of the compounds include polyvinyl acetate (with a hydrolytic ratio of 65% or more), polyacrylic acid and alkali metal salts or amine salts thereof, polyacrylic acid copolymers and alkali metal salts.or amine salts thereof, polymethacrylic acid and alkali metal salts or amine salts thereof, polymethacrylic acid copolymers and alkali metal salts or amine salts thereof, polyacrylamide and polyacrylamide copolymers, polyhydroxyethyl acrylate, polyvinyl pyrrolidone and polyvinyl pyrrolidone copolymers, polyvinyl methyl ether, polyvinyl methyl ether/maleic anhydride copolymers, poly(2-acrylamido-2-methyl-1-propane sulfonic acid) and alkali metal salts or amine salts thereof, poly(2-acrylamido-2-methyl-1-propane sulfonic acid) copolymers and alkali metal salts or amine salts thereof, gum arabic, cellulose derivatives (e.g., carboxymethylcellulose, carboxyethylcellulose, methylcellulose) and modifications thereof, white dextrin, pullulan, as well as zymolysis-etherified dextrin. These resins may be used in combinations of two or more thereof as appropriate.

The overcoat may also contain any of the photothermal conversion substances as described before as long as it is water-soluble. When the overcoat is provided by applying the coating material in the form of an aqueous solution, such a nonionic surfactant as polyoxyethylene nonylphenyl ether and polyoxyethylene dodecyl ether may be added to the material for the purpose of ensuring a uniform application.

The coating amount of the overcoat after drying is preferably 0.1 to 2.0 g/m². With a coating amount being within such a range, the heat-sensitive layer surface can be well prevented from hydrophobic contaminations, from getting fingerprints thereon, for instance, while the on-press developability is in no way impaired.

[Lithographic Platemaking Process]

The presensitized plate obtainable by using the lithographic printing plate support according to the present invention is then subjected to any of various treatment methods depending on the image recording layer provided, so as to prepare a lithographic printing plate.

Illustrative examples of sources of actinic light that may be used for imagewise exposure include mercury vapor lamps, metal halide lamps, xenon lamps and chemical lamps. Examples of laser beams that may be used include beams from helium-neon lasers (He—Ne lasers), argon lasers, krypton lasers, helium-cadmium lasers, KrF excimer lasers, semiconductor lasers, YAG lasers and YAG-SHG lasers.

Following the exposure, when the image recording layer is of a thermal positive type, thermal negative type, conventional negative type, conventional positive type or photopolymer type, it is preferable to carry out development using a developer in order to obtain the lithographic printing plate.

The developer is preferably an alkaline developer, and more preferably an alkaline aqueous solution which is substantially free of organic solvent.

Developers which are substantially free of alkali metal silicates are also preferred. One example of a suitable method of development using a developer that is substantially free of alkali metal silicates is the method described in detail in JP 11-109637 A.

Developers containing an alkali metal silicate, however, are also usable.

When the image recording layer provided is of a non-treatment type, the presensitized plate of the present invention having been subjected to imagewise exposure can be set on a printing press with no further treatments so as to carry out printing with the plate by the conventional procedures employing ink and/or fountain solution. It is also possible to subject the presensitized plate fitted onto the plate cylinder of a printing press to exposure with a laser mounted on the press and then to on-press development by applying ink and/or fountain solution to the plate, as described in JP 2938398 B. In those cases, the heat-sensitive layer is removed from the presensitized plate on the printing press with the ink and/or fountain solution for printing, so that neither a separate development process nor a temporary shutdown of the prnting press after development is required, which makes it possible to carry out printing as soon as development is completed.

It should be noted that the presensitized plate with the heat-sensitive layer of a non-treatment type may also be subjected to the development with water or a suitable aqueous solution as the developer before use for printing.

### EXAMPLES

Hereafter, the present invention is described in detail by way of examples. The present invention, however, is not limited thereto.

1. Fabrication of Presensitized Plate

### Example 1, Examples 6 to 9, and Comparative Examples 6 to 9]

Lithographic printing plate supports were obtained by subjecting aluminum plates (JIS A1050 material) with a thickness of 0.3 mm to the graining treatments as below. After each treatment or rinsing process, the solution or water remaining on the plates was removed with nip rollers.

<Graining Treatment>

Graining was carried out by performing the following surface treatments (a) to (e). sequentially.

(a) Alkali Etching Treatment

Etching treatment was performed for 10 seconds by spraying the aluminum plates as above with an aqueous solution having a caustic soda concentration of 30 g/L, an aluminum ion concentration of 10 g/L and a temperature of 60° C. so as to dissolve the plates in an amount of 0.5 g/m². Then, the aluminum plates were rinsed with a spray of water.

(b) Desmutting Treatment

Desmutting treatment was performed by spraying the aluminum plates with a 12 g/L aqueous solution of nitric acid (containing 10 g/L of aluminum ions) at a temperature of 30° C., then the plates were rinsed with a spray of water.

(c) Electrochemical Graining Treatment

Electrochemical graining treatment was performed continuously using an alternating voltage at 50 Hz. The electrolyte solution for the treatment was a 15 g/L aqueous solution of hydrochloric acid (containing 10 g/L of aluminum ions) at a temperature of 30° C. The AC power waveform was sinusoidal, and a carbon electrode was used as a counter electrode. Ferrite was used for an auxiliary anode. The electrolytic cell for the treatment was as shown in FIG. 3. The current from the power source was shunted into the auxiliary anode at a ratio of 5%.

The current density was 16 A/dm² at current peaks, and the total amount of electricity when an aluminum plate serves as an anode was 400 C/dm².

After the treatment, the aluminum plates were rinsed with a spray of water.

(d) Alkali Etching Treatment

Etching treatment was performed at a temperature of 35° C. for 10 seconds by spraying the aluminum plates with an aqueous solution having a caustic.soda concentration of 36 g/L and an aluminum ion concentration of 10 g/L so as to dissolve the plates in an amount.of 0.1 g/m². By this treatment, aluminum hydroxide-based smut components generated during the above electrochemical graining treatment with alternating current were removed, and the edges of the pits formed by the electrochemical graining treatment were dissolved to make them round. Then, the aluminum plates were rinsed with a spray of water.

(e) Desmutting Treatment

Desmutting treatment was performed for 10 seconds by spraying the aluminum plates with a 15 wt % aqueous solution of sulfuric acid (containing 10 wt % of aluminum ions) at a temperature of 30° C., then the plates were rinsed with a spray of water.

<Anodizing Treatment>

An apparatus for anodization by DC electrolysis was used to perform anodizing treatment on the aluminum plates grained as described above so as to obtain lithographic printing plate supports. Sulfuric acid was used as electrolyte. For each plate, the electrolyte solution used was a 10 wt % solution of sulfuric acid (containing 5.0 wt % of aluminum ions) at a temperature of 20° C. The current density was 6 A/dm². After the treatment, the aluminum plates were rinsed with a spray of water. The final amount of anodized layer was 2.5 g/m².

The surface roughness Ra of the lithographic printing plate supports obtained after the anodizing treatment was 0.44 μm.

<Alkali Metal Silicate Treatment>

Alkali metal silicate treatment (silicate treatment) was performed by immersing the aluminum plates having been subjected to the anodizing treatment in an aqueous sodium silicate solution in a treatment tank. The aqueous sodium silicate solutions and immersing.times employed for the treatment were as set forth in Table 1. After the treatment, the aluminum plates were rinsed with a spray of well water, and the lithographic printing plate supports subjected to the alkali metal silicate treatment were thus obtained.

TABLE 1

| Example, | Aqueous sodium silicate solution | | | |
|---|---|---|---|---|
| Comparative | Concentration | | Temperature | Time |
| Example | (wt %) | pH | (° C.) | (sec) |
| EX1-EX5 | 3.5 | 12.0 | 22 | 8 |
| CE1-CE5 | | | | |
| EX6 | 1.0 | 11.5 | 50 | 8 |
| EX7 | 2.0 | 13.0 | 20 | 8 |
| EX8 | 4.0 | 12.0 | 22 | 3 |
| EX9 | 2.0 | 13.0 | 50 | 10 |
| CE6 | 1.0 | 11.2 | 20 | 8 |
| CE7 | 1.0 | 11.5 | 20 | 5 |
| CE8 | 2.0 | 13.0 | 70 | 10 |
| CE9 | 4.0 | 13.7 | 25 | 10 |

EX: Example
CE: Comparative Example

<Formation of Intermediate Layer>

Intermediate layers were formed on the lithographic printing plate supports as above by applying the coating solution for intermediate layer having the following composition to the supports and drying the supports at a temperature of 100° C. for 8 seconds.

<Coating Solution for Intermediate Layer>

| | | |
|---|---|---|
| Polymeric compound of composition “No. 1” | 0.3 | g |
| in Table 2 below | | |
| Methanol | 100 | g |
| Water | 1 | g |

TABLE 2

| | Constituent with | Constituent with |
|---|---|---|
| | acid group | onium group |
| No. 1 | 70% | 30% |
| No. 2 | 60% | 40% |
| No. 3 | 80% | 20% |

In Table 2, the constituent with acid group is a monomer expressed by formula (13) as below and that with onium group is a monomer expressed by formula (14) as below. The coating amount of the intermediate layers was 17 mg/M². 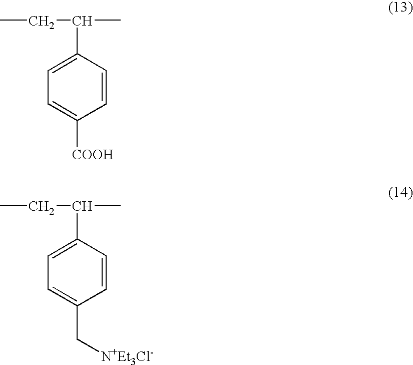
<Formation of Image Recording Layer>

The coating solution A1 for image recording layer having the following composition was applied onto the intermediate layers with a wire bar so that the coating amount might be 0.85 g/m² after drying, and caused to dry at a temperature of 140° C. for 50 seconds.

Subsequently, the coating solution B1 for image recording layer having the following composition was so applied with a wire bar that the coating amount might be 0.25 g/m² after drying, and caused to dry at a temperature of 140° C. for 1 minute. The laminated image recording layers of a thermal positive type were thus formed so as to obtain presensitized plates.

| | |
|---|---|
| <Coating Solution A1 for Image Recording Layer> | |
| N-(4-aminosulfonylphenyl)methacrylamide/ | 1.920 g |
| acrylonitrile/methyl methacrylate copolymer | |
| (molar ratio, 36/34/30; weight-average molecular | |
| weight, 50,000) | |
| m,p-Cresol novolak (m-cresol novolak/p-cresol novolak = | 0.213 g |
| 6/4; weight-average molecular weight, 4,000) | |
| Cyanine dye A of the following formula | 0.032 g |
| 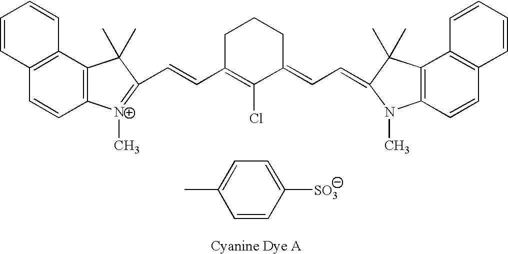 | |
| p-Toluenesulfonic acid | 0.008 g |
| Tetrahydrophthalic anhydride | 0.190 g |
| Bis (p-hydroxyphenyl) sulfone | 0.126 g |
| 2-methoxy-4-(N-phenylamino)benzenediazonium | 0.032 g |
| hexafluorophosphate | |
| Dye obtained by substituting 1-naphthalenesulfonic | 0.078 g |
| acid anions for the counterions of Victoria Pure | |
| Blue BOH | |
| Fluorocarbon surfactant (Megafac F-780, available | 0.020 g |
| from Dainippon Ink and Chemicals, Inc.) | |
| γ-Butyrolactone | 13.180 g |
| Methyl ethyl ketone | 25.410 g |
| 1-Methoxy-2-propanol | 12.970 g |
| <Coating Solution B1 for Image Recording Layer> | |
| Phenol/m,p-cresol novolak (phenol/m-cresol novolak/ | 0.274 g |
| p-cresol novolak = 5/3/2; weight-average molecular | |
| weight, 4,000) | |
| Cyanine dye A of the above formula | 0.029 g |
| Structural polymer B of the following formula 30 wt % | 0.140 g |
| methyl ethyl ketone solution | |
| 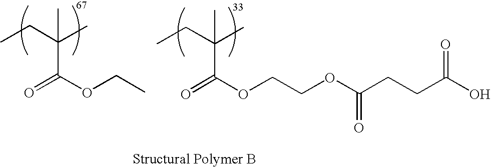 | Mw 50 THOUSAND |
| Quaternary ammonium salt C of the following formula | 0.004 g |
| 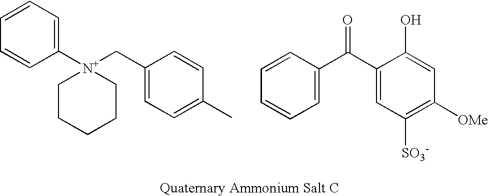 | |
| Sulfonium salt D of the following formula | 0.065 g |
| 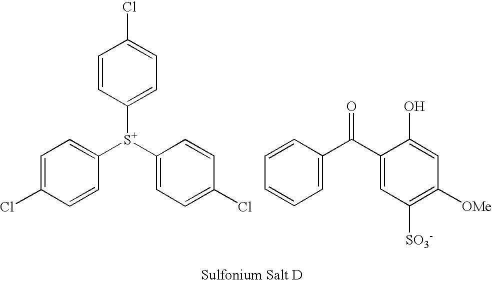 | |
| Fluorocarbon surfactant (Megafac F-780, available | 0.004 g |
| from Dainippon Ink and Chemicals, Inc.) | |
| Fluorocarbon surfactant (Megafac F-782, available | 0.020 g |
| from Dainippon Ink and Chemicals, Inc.) | |
| Methyl ethyl ketone | 10.39 g |
| 1-Methoxy-2-propanol | 20.98 g |

### Example 2

A presensitized plate was fabricated by following the procedure of Example 1 except that the current density was 12 A/dm² and the amount of electricity was 300 C/dm² in treatment (c) as above. The surface roughness Rₐ of the lithographic printing plate support obtained after the anodizing treatment was 0.34 μm.

### Example 3

A presensitized plate was fabricated by following the procedure of Example 1 except that the current density was 24 A/dm² and the amount of electricity was 600 C/dm² in treatment (c) . The surface roughness Rₐ of the lithographic printing plate support obtained after the anodizing treatment was 0.64 μm.

### Example 4

A presensitized plate was fabricated by following the procedure of Example 1 except that the electrolytic cell as shown in FIG. 2 was used to carry out electrochemical graining in treatment (c) and the temperature of the aqueous solution of caustic soda was 30° C. in treatment (d)

### Example 5

A presensitized plate was fabricated by following the procedure of Example 1 except that the electrolytic cell as shown in FIG. 2 was used to carry out electrochemical graining in treatment (c) and the temperature of the aqueous solution of caustic soda was 45° C. in treatment (d)

### Example 10

A presensitized plate was fabricated by following the procedure of Example 1 except that the coating solution for intermediate layer contained a polymeric compound of composition “No. 2” in Table 2.

### Example 11

A presensitized plate was fabricated by following the procedure of Example 1 except that the coating solution for intermediate layer contained a polymeric compound of composition “No. 3” in Table 2.

### Comparative Example 1

A presensitized plate was fabricated by following the procedure of Example 1 except that the current density was 12 A/dm² and the amount of electricity was 50 C/dm² in treatment (c) as above.

### Comparative Example 2

A presensitized plate was fabricated by following the procedure of Example 1 except that the temperature of the aqueous solution of caustic soda was 60° C. in treatment (d)

### Comparative Example 3

A presensitized plate was fabricated by following the procedure of Example 1 except that treatments (a) and (b) were replaced with the following.treatments (h), (i) and (j). The surface roughness Rₐ of the lithographic printing plate support obtained after the anodizing treatment was 0.55 μm.

(h) Mechanical Graining Treatment

Using the equipments as shown in FIG. 1, mechanical graining treatment was performed on the aluminum plate in such a manner that rotating nylon roller brushes were applied to the plate while feeding the plate surface with an abrasive slurry as a suspension (with a specific gravity of 1.12) of an abrasive (silica sand) in water. The abrasive had a mean particle size of 8 μm and a maximum particle size of 50 μm. The bristles of the nylon brushes were made of nylon 6.10, and had a length of 50 mm and a diameter of 0.3 mm. The nylon brushes were fabricated by inserting the bristles tightly in holes provided in stainless steel cylinders with a diameter of 300 mm. The rotating brushes used were three in number. Two support rollers (with a diameter of 200 mm) under each brush were 300 mm distant from each other. Each roller brush was pressed onto the aluminum plate to such an extent that the load on the motor for rotatively driving the relevant brush was increased by 7 kW with respect to that before the pressing of the brush. The rotational direction of the brushes was the same as the direction in which the aluminum plate was moved. The number of revolutions of the brushes was 200 rpm.

(i) Alkali Etching Treatment

Etching treatment was performed for 10 seconds by spraying the aluminum plate having been grained mechanically as above with an aqueous solution having a caustic soda concentration of 26.wt %, an aluminum ion concentration of 6.5 wt % and a temperature of 70° C. so as to dissolve the aluminum plate in an amount of 6 g/m². Then, the aluminum plate was rinsed with a spray of water.

(j) Desmutting Treatment

Desmutting treatment was performed by spraying the aluminum plate with a 1 wt % aqueous solution of nitric acid (containing 0.5 wt % of aluminum ions) at a temperature of 30° C., then the plate was rinsed with a spray of water.

### Comparative Example 4

A presensitized plate was fabricated by following the procedure of Comparative Example 3 except that the pumice with a mean particle size of 50 μm and a maximum particle size of 150 μm was used as the abrasive instead of silica sand and the number of revolutions of the brushes was 250 rpm in treatment (h), the amount of aluminum dissolved was 8 g/m² in treatment (i), as well as treatments (c), (d) and (e) were replaced with the following treatments (k), (1) and (m) . The surface roughness Rₐ of the lithographic printing plate support obtained after the anodizing treatment was 0.55 μm.

(k) Electrochemical Graining Treatment

Electrochemical graining treatment was performed continuously using an alternating voltage at 60 Hz. The electrolyte solution for the treatment was a 10.5 g/L aqueous solution of nitric acid (containing 5 g/L of aluminum ions) at a temperature of 50° C. The AC power waveform was as shown in FIG. 5, that is to say, an alternating current of trapezoidal waveform was employed on condition that the time TP for the transition of current value from zero to peak was 0.8 msec and the duty ratio was 1:1. A carbon electrode was used as a counter electrode, and ferrite was used for an auxiliary anode. The electrolytic cell for the treatment was as shown in FIG. 4. The current from the power source was shunted into the auxiliary anodes at a ratio of 5%.

The current density was 30 A/dm2 at current peaks, and the total amount of electricity when an aluminum plate serves as an anode was 220 C/dm².

After the treatment, the aluminum plate was rinsed with a spray of water.

(1) Alkali Etching Treatment

Etching treatment was performed at a temperature of 60° C. by spraying the aluminum plate with an aqueous solution having a caustic soda concentration of 26 wt % and an aluminum ion concentration of 6.5 wt % so as to dissolve the plate in an amount of 1.0 g/m². By this treatment, aluminum hydroxide-based smut components generated during the above electrochemical graining treatment with alternating current were removed, and the edges of the pits formed by the electrochemical graining treatment were dissolved to make them round. Then, the aluminum plate was rinsed with a spray of water.

(m) Desmutting Treatment

Desmutting treatment was performed by spraying the aluminum plate with a 15 wt % aqueous solution of sulfuric acid (containing 4.5 wt % of aluminum ions) at a temperature of 30° C., then the plate was rinsed with a spray of water.

### Comparative Example 5

A presensitized plate was fabricated by following the procedure of Comparative Example 4 except that treatment (h) was omitted, and the temperature of the aqueous caustic soda solution was 32° C. and the amount of aluminum dissolved was 0.2 g/m² in treatment (1). The surface roughness Rₐ of the lithographic printing plate support obtained after the anodizing treatment was 0.25 μm.

2. Measurement of Surface Shape of Lithographic Printing Plate Support

With respect to the pits in the surface of each of the lithographic printing plate supports obtained as described before, the following measurements (1) to (3) were performed.

Measurement results are set forth in Table 3 below. In the table, “−” denotes that the found value did not fall within a comparable range.

(1) Measurement of Mean Aperture Diameter of Large Pits

A scanning electron microscope (SEM) was used to photograph the support surface at 1,000× magnification from right above. In the SEM photograph obtained, 50 large pits with continuous annular edges were extracted to read their diameters as the aperture diameter, and then the mean aperture diameter was calculated.

(2) Measurement of Mean Aperture Diameter of Small Pits

A scanning electron microscope (SEM) of high resolution was used to photograph the support surface at 50,000× magnification from right above. In the SEM photograph obtained, 50 small pits were extracted to read their diameters as the aperture diameter, and then the mean aperture diameter was calculated.

(3) Measurement of Mean Ratio of Depth to Aperture Diameter of Small Pits

A scanning electron microscope (SEM) of high resolution was used to photograph the fracture surface of the support at 50,000× magnification. In the SEM photograph obtained, 20 small pits with an aperture diameter of 0.8 μm or less were extracted to read their aperture diameters and depths and find the ratio of depth to aperture diameter of the individual pits, and then the mean ratio was calculated.

3. Calculation of Surface Area Difference ΔS⁵⁰ of Lithographic Printing Plate Support

The surface area difference ΔS⁵⁰ of the surface of each of the lithographic printing plate supports obtained as described before was determined in the following manner.

The results are set forth in Table 3.

i) Measurement of Surface Shape with Atomic Force Microscope

An atomic force microscope (SPI3700 manufactured by Seiko Instruments Inc.) was used to measure the surface shape so as to obtain three-dimensional data. Specific procedure was as follows.

A 1 cm square sample was cut out from the lithographic printing plate support and set on a horizontal sample holder mounted on a piezoelectric scanner. A cantilever was caused to approach the surface of the sample until atomic forces were appreciable and then the surface was scanned in the X and Y directions to acquire the surface asperities of the sample based on the piezoelectric displacement in the Z direction. The piezoelectric scanner used is capable of scanning 150 μm in the X and Y directions and 10 μm in the Z direction, and the cantilever (AC-160TS manufactured by Olympus Corporation) has a resonance frequency of 120 to 150 kHz and a spring constant of 12 to 20 N/m. Measurement was carried out in the dynamic force mode (DFM). The three-dimensional data obtained was approximated by the least-squares method to compensate for slight tilting of the sample and determine a reference plane.

Measurement was performed at 512×512 points in a 50 μm square region of the sample surface. The resolution was 1.9 μm in the X and Y directions and 1 nm in the Z direction, and the scan rate was 60 μm/sec.

ii) Calculation of Surface Area Difference ΔS⁵⁰

Using the three-dimensional data (f(x, y)) obtained in i) above, sets of adjacent three points were extracted and the areas of the minimal triangles formed by the individual sets of three points were summated, with the summation being assumed as the actual area Sₓ⁵⁰. The surface area difference ΔS⁵⁰ was calculated from the resulting actual area Sₓ⁵⁰ and the geometrically measured area S₀⁵⁰ using equation (1) as below.
ΔS⁵⁰=(Sₓ⁵⁰−S₀⁵⁰)/S₀⁵⁰×100 (%) (1)
4. Measurement of Amount of Si Atoms Deposited to Support Surface

The amount of the Si atoms deposited to the surface of each lithographic printing plate support was measured by a calibration curve method using an X-ray fluorescence spectrometer. The results are set forth in Table 3. In this regard, the values in the table were corrected based on the amounts of the Si atoms present in the aluminum plates.

The reference material for the preparation of calibration curve was an aqueous sodium silicate solution containing a known amount of Si atoms, which was uniformly dropped onto a region of 30 mm in diameter of the surface of the relevant aluminum plate and then caused to dry. Conditions for X-ray fluorescence spectrometry were as follows.
X-ray fluorescence spectrometer: RIX3000 manufactured by Rigaku Industrial Corporation.
X-ray tube: Rh.
Spectrum to measure: Si—Kα.
Tube voltage: 50 kV.
Tube current: 50 mA.
Slit: COARSE.
Light-dispersing crystal: RX4.
Detector: F—PC.
Region for spectrometry: circular one of 30 mm in diameter.
Peak position (20): 144.75 deg.
Background (20): 140.70 deg. and 146.85 deg.
Integrating time: 80 sec/sample.
   5. Evaluation of Presensitized Plate

The presensitized plates fabricated as described before were evaluated with respect to the press life, resistance to scumming by ink spreading, resistance to scumming by leaving, water visibility, and resistance to scumming by failed deletion according to the methods as below.

<Exposure and Development of Presensitized Plate>

Trendsetter manufactured by Creo was used to subject the presensitized plates as above to the exposure at a beam intensity of 10 W and a drum rotation speed of 150 rpm so as to form on each plate an image, of the test pattern produced with an FM screen (Staccato20 manufactured by Creo).

Then, the PS processor 940H manufactured by Fuji Photo Film Co., Ltd. was charged with the developer prepared by diluting the developer DT-2 from Fuji Photo Film Co., Ltd. with eight parts of water (with an electrical conductivity of about 43 mS/cm) and the finisher prepared by diluting the finisher FG-1 from Fuji Photo Film Co., Ltd. with one part of water, and the presensitized plates having been exposed were developed for 12 seconds by using the processor while maintaining the developer and finisher at a temperature of 30° C., to thereby obtain lithographic printing plates.

(1) Resistance to Scumming by Ink Spreading

The lithographic printing plates prepared as described above were set on the printing press SOR-M manufactured by Heidelberg, and printing was carried out using the fountain solution IF102 3% (from Fuji Photo Film Co., Ltd.) and Values (N) black ink (from Dainippon Ink and Chemicals, Inc.). The extent of scumming by ink spreading in a region of shadows (with a halftone dot area ratio of 80%) was evaluated by visual inspection as the amount of fountain solution was gradually reduced from the standard amount. The results are set forth in Table 3. Meanings of the marks in the table are as follows.

◯: No scumming by ink spreading was generated.

Δ: Scumming by ink spreading was so generated that the halftone was partially plugged.

×: Scumming by ink spreading was so generated that the halftone was plugged almost completely.

(2) Press Life

With the lithographic printing plates prepared as described above, printing was carried out on Lithrone printing press manufactured by Komori Corporation using DIC-Values (N) black ink from Dainippon Ink and Chemicals, Inc. The press life of each plate was evaluated by the number of the printed sheets which had already been made from the relevant plate at the time when the density of solid images began to decline on visual inspection. The results are set forth in Table 3.

(3) Resistance to Scumming by Leaving

The lithographic printing plates prepared as described above were set on the printing press SOR-M manufactured by Heidelberg, and 5,000 printed sheets were made from each plate using the fountain solution IF102 3% (from Fuji Photo Film Co., Ltd.) and Values (N) black ink (from Dainippon Ink and Chemicals, Inc.) before the plates were detached from the printing press to leave them to stand for one hour. After one hour, the lithographic printing plates were again set on the printing press to carry out printing. The resistance to scumming by leaving of each plate was evaluated by the number of the printed sheets which had already been made from the relevant plate at the time when normal printing was restored, with no scumming being generated on a printed material. The smaller the number of printed sheets is, the more excellent the resistance to scumming by leaving is. The results are set forth in Table 3.

(4) Water Visibility

The lithographic printing plates prepared as described above were set on the printing press SOR-M manufactured by Heidelberg, and the shininess in the non-image areas of the surface of each plate was observed visually while increasing the amount of fountain solution fed. The water visibility was evaluated in terms of the amount of the fountain solution having been fed by the time when the non-image areas began to shine.

The results are set forth in Table 3. Meanings of the marks in the table are as follows.

◯: A large amount of fountain solution had been fed by the time when the non-image areas began to shine.

×: Only a small amount of fountain solution had been fed by the time when the non-image areas began to shine.

(5) Resistance to Scumming by Failed Deletion

Unwanted image recording layer portions of the lithographic printing plates prepared as described above were removed by using the deletion fluid PR-2 (from Fuji Photo Film Co., Ltd.), then the plates were rinsed with water. The removal was carried out for an deletion time varying from 10 to 120 seconds in ten-second steps.

Subsequently, the lithographic printing plates having been rinsed were set on a printing press (DAIYA) manufactured by Mitsubishi Heavy Industries, Ltd., and 1,000 printed sheets were made from each plate using the fountain solution IF102 3% (from Fuji Photo Film Co., Ltd.) and GEOS (S) magenta ink (from Dainippon Ink and Chemicals, Inc.). The resistance to scumming by failed deletion was evaluated by visual inspection. The results are set forth in Table 3. Meanings of the mark in the table are as follows.

◯: The deletion time required for a complete removal of unwanted image recording layer portions was not more than 30 seconds.

TABLE 3

| | | | Ratio of | Surface | | | Resis- | | Resis- | |
|---|---|---|---|---|---|---|---|---|---|---|
| | Large | Small | depth to | area | | | tance to | Resis- | tance to | |
| | pit | pit | aperture | differ- | | Press | scumming | tance to | scumming | |
| | aperture | aperture | diameter | ence | Amount of | life | by | scumming | by | Water |
| | diameter | diameter | of small | ΔS⁵⁰ | deposited | (thousand | leaving | by ink | failed | visi- |
| | (μm) | (μm) | pits | (%) | Si atoms | sheets) | (sheets) | spreading | deletion | bility |
| EX1 | 5 | 0.20 | 0.34 | 30 | 5.2 | 70 | 80 | ◯ | ◯ | ◯ |
| EX2 | 2 | 0.20 | 0.34 | 27 | 5.0 | 75 | 60 | ◯ | ◯ | ◯ |
| EX3 | 8 | 0.20 | 0.34 | 35 | 5.3 | 65 | 70 | ◯ | ◯ | ◯ |
| EX4 | 5 | 0.05 | 0.60 | 40 | 5.5 | 75 | 80 | ◯ | ◯ | ◯ |
| EX5 | 5 | 0.60 | 0.20 | 20 | 4.5 | 65 | 70 | ◯ | ◯ | ◯ |
| EX6 | 5 | 0.20 | 0.34 | 27 | 5.2 | 70 | 80 | ◯ | ◯ | ◯ |
| EX7 | 5 | 0.20 | 0.34 | 27 | 5.2 | 70 | 80 | ◯ | ◯ | ◯ |
| EX8 | 5 | 0.20 | 0.34 | 27 | 3.0 | 75 | 80 | ◯ | ◯ | ◯ |
| EX9 | 5 | 0.20 | 0.34 | 27 | 15.0 | 65 | 80 | ◯ | ◯ | ◯ |
| EX10 | 5 | 0.20 | 0.34 | 30 | 5.2 | 75 | 80 | ◯ | ◯ | ◯ |
| EX11 | 5 | 0.20 | 0.34 | 30 | 5.2 | 75 | 80 | ◯ | ◯ | ◯ |
| CE1 | — | 0.20 | 0.34 | 15 | 5.0 | 30 | 100 | X | ◯ | X |
| CE2 | 5 | 0.90 | 0.15 | 20 | 4.5 | 20 | 60 | ◯ | ◯ | ◯ |
| CE3 | 12 | 0.20 | 0.34 | 30 | 5.2 | 50 | 140 | Δ | ◯ | ◯ |
| CE4 | 15 | 1.20 | 0.10 | 23 | 4.7 | 20 | 80 | ◯ | ◯ | ◯ |
| CE5 | — | — | — | 28 | 5.7 | 70 | 80 | ◯ | ◯ | X |
| CE6 | 5 | 0.20 | 0.34 | 30 | 3.0 | 70 | 80 | X | ◯ | ◯ |
| CE7 | 5 | 0.20 | 0.34 | 30 | 2.0 | 70 | 90 | X | ◯ | ◯ |
| CE8 | 5 | 0.20 | 0.34 | 30 | 20.5 | 20 | 70 | ◯ | ◯ | ◯ |
| CE9 | 5 | 0.20 | 0.34 | 30 | 5.2 | 60 | 200 | ◯ | ◯ | ◯ |

EX: Example
CE: Comparative Example

As seen from Table 3, the presensitized plates according to the present invention (Examples 1 to 11) are excellent in all of the resistance to scumming by ink spreading, press life, resistance to, scumming by leaving, resistance to scumming by failed deletion, and water visibility when an FM screen is used for halftone.

What is claimed is:

1. A lithographic printing plate support obtainable by subjecting an aluminum plate to.an electrochemical graining treatment with an aqueous solution containing hydrochloric acid, anodizing treatment and alkali metal silicate treatment at least, wherein: a surface of the support has a grained shape in which large pits with a mean aperture diameter of 2 to 10 μm and small pits with a mean aperture diameter of 0.05 to 0.8 μm overlap with each other, with the mean ratio of depth to aperture diameter of the small pits being 0.2 to 0.6; a surface area difference ΔS⁵⁰ defined by equation (1):
ΔS⁵⁰=(Sₓ⁵⁰−S₀⁵⁰)/S₀⁵⁰×100 (%) (1)
in which Sₓ⁵⁰ is the actual area of a 50 μm square region of the surface as determined by three-point approximation from three-dimensional data obtained by measuring the region with an atomic force microscope at 512×512 points and S₀⁵⁰ is the geometrically measured area of the same region, is 20 to 40%; the alkali metal silicate treatment is performed using an aqueous solution of pH 11.5 to 13.0 which contains an alkali metal silicate; and an amount of Si atoms deposited to the surface is 3.0 to 15.0 mg/m².

2. A presensitized plate comprising the lithographic printing plate support according to claim 1 on which an image recording layer allowing an image to be formed by heat is provided.

3. The presensitized plate according to claim 2, wherein an intermediate layer is provided between the lithographic printing plate support and the image recording layer, and the intermediate layer is formed with a polymeric material which includes a constituent bearing an acid group and a constituent bearing an onium group.

4. The presensitized plate according to claim 3, wherein the intermediate layer contains a polymeric compound which includes 60 to 80 mol % of the constituent bearing an acid group and 20 to 40 mol % of the constituent bearing an onium group.
